(19) United States
(12) Patent Application Publication
(10) Pub. No.: US 2026/0163544 A1
(43) Pub. Date: Jun. 11, 2026

(54) ELECTRONIC COMPONENT

(71) Applicant: Murata Manufacturing Co., Ltd., Kyoto-fu (JP)

(72) Inventor: Hiromitsu ITO, Nagaokakyo-shi (JP)

(73) Assignee: Murata Manufacturing Co., Ltd., Kyoto-fu (JP)

(21) Appl. No.: 19/180,450

(22) Filed: Apr. 16, 2025

Related U.S. Application Data
(63) Continuation of application No. PCT/JP2023/030362, filed on Aug. 23, 2023.

(30) Foreign Application Priority Data
Nov. 29, 2022 (JP) 2022-190514

(51) Int. Cl. H03H 7/06; H01F 17/00; H01F 17/03; H01F 27/02; H01F 27/29; H01F 27/40; H01G 4/228

(52) U.S. Cl. CPC H03H 7/06; H01F 17/03; H01F 27/022; H01F 27/292; H01F 27/40; H01G 4/228; H01F 2017/002; H01F 2017/0026

(57) ABSTRACT

An electronic component comprising a glass substrate having a first surface and a second surface that are positioned on opposite sides from each other; a coil a portion of which is embedded in the glass substrate and which is wound about an axis; and a capacitor provided to the glass substrate, electrically connected to the coil, and having a first electrode and a second electrode that face each other. The first electrode and the second electrode overlap the coil in a direction perpendicular to the axis.

### CROSS REFERENCE TO RELATED APPLICATION

This application claims benefit of priority to International Patent Application No. PCT/JP2023/030362, filed Aug. 23, 2023, and to Japanese Patent Application 2022-190514 filed Nov. 29, 2022, the entire content of each are incorporated herein by reference.

### BACKGROUND

### Technical Field

The present disclosure relates to an electronic component.

### Background Art

A conventional electronic component is described in JP-A-2020-174169. The electronic component includes a glass substrate, an outer surface conductor in contact with an outer surface of the glass substrate, and a protective film in contact with the outer surface of the glass substrate and the outer surface conductor so as to cover the outer surface conductor. In this electronic component, an aspect (FIG. 16) including a capacitor and a coil is described, the capacitor has a first electrode and a second electrode, and the coil is formed by helically winding a conductor along an axis.

### SUMMARY

In the conventional electronic component, the first electrode of the capacitor is arranged horizontally in the axial direction with respect to the coil. However, such a configuration has a problem that it is difficult to reduce the size with respect to the plane direction parallel to the axial direction.

Therefore, the present disclosure provides an electronic component that can be downsized.

An electronic component according to one aspect of the present disclosure comprises a glass substrate having a first surface and a second surface that are positioned on opposite sides from each other; a coil a portion of which is embedded in the glass substrate and which is wound about an axis; and a capacitor provided to the glass substrate, electrically connected to the coil, and having a first electrode and a second electrode that face each other. The first electrode and the second electrode overlap the coil in a direction perpendicular to the axis.

In the above aspect, by a configuration in which the first electrode and the second electrode of the capacitor and the coil overlap in the direction (plan view) perpendicular to the axis, the size in the plane direction parallel to the axis can be reduced, and the electronic component can be downsized. For example, in a case where the second surface side of the glass substrate is the mounting surface, the mounting area can be reduced.

According to the present disclosure, it is possible to provide an electronic component that can be downsized.

### BRIEF DESCRIPTION OF THE DRAWINGS

FIG. 1 shows a top view of an electronic component according to a first embodiment;

FIG. 2 shows a cross-sectional view taken along line II-II of FIG. 1;

FIG. 3 shows a cross-sectional view taken along line III-III of FIG. 1;

FIG. 4 shows a top view of an electronic component according to a second embodiment;

FIG. 5 shows a cross-sectional view taken along line V-V of FIG. 4;

FIG. 6 shows a cross-sectional view taken along line VI-VI of FIG. 4;

FIG. 7 shows a top view of an electronic component according to a third embodiment;

FIG. 8 shows a cross-sectional view taken along line VIII-VIII of FIG. 7;

FIG. 9 shows a cross-sectional view taken along line IX-IX of FIG. 8;

FIG. 10 shows a top view of an electronic component according to a fourth embodiment;

FIG. 11 shows a cross-sectional view taken along line XI-XI of FIG. 10;

FIG. 12 shows a cross-sectional view taken along line XII-XII of FIG. 11;

FIG. 13 shows a top view of an electronic component according to a fifth embodiment;

FIG. 14 shows a cross-sectional view taken along line XIV-XIV of FIG. 13;

FIG. 15 shows a cross-sectional view taken along line XV-XV of FIG. 13;

FIG. 16 shows a top view of an electronic component according to a sixth embodiment;

FIG. 17 shows a cross-sectional view taken along line XVII-XVII of FIG. 16;

FIG. 18 shows a cross-sectional view taken along line XVIII-XVIII of FIG. 16;

FIG. 19 shows a top view of an electronic component according to a seventh embodiment;

FIG. 20 shows a cross-sectional view taken along line XX-XX of FIG. 19;

FIG. 21 shows a cross-sectional view taken along line XXI-XXI of FIG. 19;

FIG. 22 shows a cross-sectional view taken along line XXII-XXII of FIG. 19;

FIG. 23 shows a top view of an electronic component according to an eighth embodiment;

FIG. 24 shows a cross-sectional view taken along line XXIV-XXIV of FIG. 23;

FIG. 25 shows a cross-sectional view taken along line XXV-XXV of FIG. 23;

FIG. 26 shows a top view of an electronic component according to a ninth embodiment;

FIG. 27 shows a cross-sectional view taken along line XXVII-XXVII of FIG. 26;

FIG. 28 shows a cross-sectional view taken along line XXVIII-XXVIII of FIG. 26;

FIG. 29 shows a top view of an electronic component according to a tenth embodiment;

FIG. 30 shows a cross-sectional view taken along line XXX-XXX of FIG. 29;

FIG. 31 shows a cross-sectional view taken along line XXXI-XXXI of FIG. 29;

FIG. 32 shows an exploded plan view of FIG. 29;

FIG. 33 shows a cross-sectional view of an electronic component according to an eleventh embodiment; and

FIG. 34 shows a cross-sectional view of an electronic component according to a twelfth embodiment.

### DETAILED DESCRIPTION

A magnetic particle of one aspect of the present disclosure will now be described in detail with reference to shown embodiments. Drawings include partially schematic drawings and may not reflect actual dimensions or ratios.

### First Embodiment

### Overview Configuration

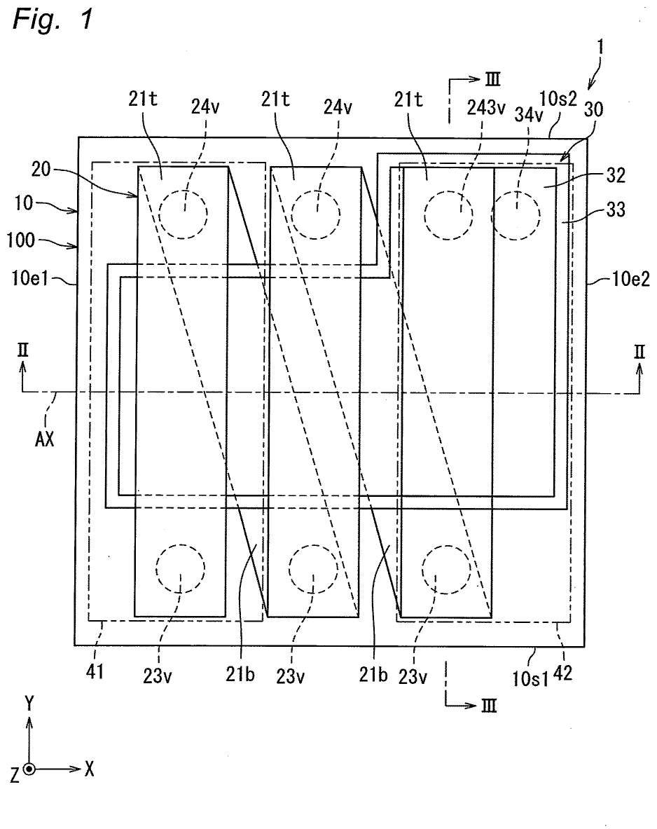

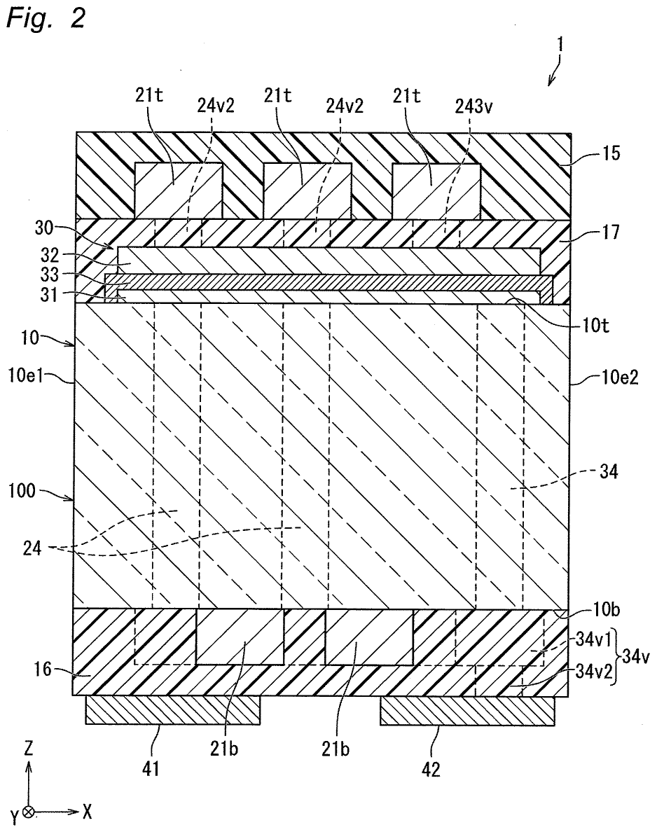

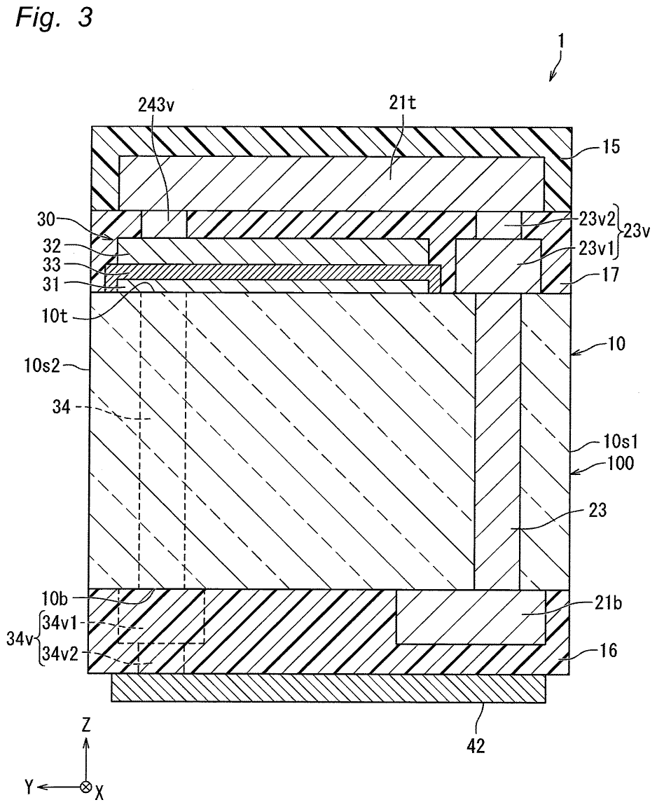

FIG. 1 shows a schematic top view of an electronic component 1 as viewed from a top surface side. FIG. 2 shows a cross-sectional view taken along line II-II of FIG. 1. FIG. 3 shows a cross-sectional view taken along line III-III of FIG. 1. Note that, for convenience, FIG. 1 is illustrated in a transparent manner so that the structure can be easily understood, but may be translucent or opaque. In FIG. 1, a first external terminal 41 and a second external terminal 42 are indicated by two-dot diagonal lines, and a first protective layer 15 and a third protective layer 17 are omitted.

As shown in FIGS. 1, 2, and 3, the electronic component 1 includes a glass substrate 10, a coil 20, a capacitor 30, the third protective layer 17, the first protective layer 15, a second protective layer 16, the first external terminal 41, and the second external terminal 42. The electronic component 1 is, for example, a surface mount electronic type electronic component used for a high frequency signal transmission circuit.

The glass substrate 10 has a first surface 10t and a second surface 10b positioned on opposite sides from each other.

A portion of the coil 20 is embedded in the glass substrate 10 and the coil 20 is wound about an axis AX. A portion of the coil 20 is exposed from above the first surface 10t of the glass substrate 10. A portion of the coil 20 is exposed from above the second surface 10b of the glass substrate 10.

The capacitor 30 is provided to the first surface 10t of the glass substrate 10 and is electrically connected to the coil 20. The capacitor 30 has a first electrode 31 and a second electrode 32 facing each other, and the first electrode 31 and the second electrode 32 overlap the coil 20 in a direction perpendicular to the axis AX. With the above configuration, the size in the plane direction parallel to the axis AX can be reduced, and the electronic component 1 can be downsized. For example, in a case where the second surface 10b side of the glass substrate 10 is the mounting surface, the mounting area can be reduced.

The third protective layer 17 covers the capacitor 30 and is provided on the first surface 10t of the coil 20.

The first protective layer 15 covers a portion of the exposed coil 20 and is provided on the third protective layer 17.

The second protective layer 16 covers a portion of the exposed coil 20 and is provided on the second surface 10b of the coil 20.

The first external terminal 41 and the second external terminal 42 are provided on the second protective layer 16. The first external terminal 41 is electrically connected to the coil 20, and the second external terminal 42 is electrically connected to the capacitor 30. The coil 20 and the capacitor 30 are connected in series. The coil 20 and the capacitor 30 may be connected in parallel.

### Preferred Configuration of Each Member

### Glass Substrate 10

The glass substrate 10 is a rectangular parallelepiped having a length, a width, and a height. The glass substrate 10 has a first end surface 10e1 and a second end surface 10e2 positioned on both end sides in the length direction, a first side surface 10s1 and a second side surface 10s2 on both end sides in the width direction, and the second surface 10b and the first surface 10t on both end sides in the height direction. That is, an outer surface 100 of the glass substrate 10 includes the first end surface 10e1 and the second end surface 10e2, the first side surface 10s1 and the second side surface 10s 2, and the second surface 10b and the first surface 10t. The second surface 10b is one of the main surfaces of the glass substrate 10, and the first surface 10t is positioned on a back side of the second surface 10b. The first surface 10t and the second surface 10b are parallel to the axis AX.

In this specification, “parallel” includes not only being completely parallel to the axis AX of the coil but also being substantially parallel, for example, being slightly curved with respect to the axis AX, and includes, for example, having an angle of ±5% with respect to the axis AX.

In this specification, the outer surface 100 of the glass substrate 10 does not simply mean a surface facing the outer peripheral side of the glass substrate 10, but is a surface serving as a boundary between the outside and the inside of the glass substrate 10. In addition, “above the outer surface 100 of the glass substrate 10” refers to not an absolute direction such as a vertical upward direction defined in the direction of gravity, but a direction toward the outside with respect to the outer surface 100 which is a boundary between the outside and the inside with the outer surface 100 as a reference. Therefore, “above the outer surface 100” is a relative direction determined by the direction of the outer surface 100. In addition, “above” with respect to an element includes not only an upper position away from the element, that is, an upper position via another object on the element or an upper position with space, but also a position immediately above (on) the element in contact with the element.

As illustrated in the drawings, hereinafter, for convenience of description, a direction of the length direction (the longitudinal direction) of the glass substrate 10 and a direction from the first end surface 10e1 toward the second end surface 10e2 is defined as an X direction. In addition, a direction of the width direction of the glass substrate 10 and a direction from the first side surface 10s1 toward the second side surface 10s2 is defined as a Y direction. In addition, a direction of the height direction of the glass substrate 10 and a direction from the second surface 10b toward the first surface 10t is defined as a Z direction. The X direction, the Y direction, and the Z direction are directions perpendicular to each other, and when arranged in the order of X, Y, and Z, form a left-handed coordinate system.

The glass substrate 10 has an insulating property. The glass substrate 10 is preferably, for example, a glass substrate having photosensitivity represented by FoturanII (registered trademark of SchottAG). In particular, the glass substrate 10 preferably includes cerium oxide (ceria: CeO₂), and in this case, the cerium oxide serves as a sensitizer, and processing by photolithography becomes easier.

However, since the glass substrate 10 can be processed by machining such as drilling and sandblasting, dry/wet etching processing using a photoresist/metal mask, laser processing, or the like, it may be a glass plate having no photosensitivity. The glass substrate 10 may be obtained by sintering a glass paste, or may be formed by a known method such as a float method.

### Coil 20

The coil 20 is helically wound along the axis AX. The axis AX of the coil 20 is arranged parallel to the second surface 10b of the glass substrate 10. The coil 20 includes a plurality of second coil conductors 21b, a plurality of first coil conductors 21t, a plurality of first through conductors 23, and a plurality of second through conductors 24. In the coil 20, the first through conductors 23, the first coil conductors 21t, the second through conductors 24, and the second coil conductors 21b are electrically connected in this order to form a spiral.

The coil 20 has a first end and a second end, and the second end is connected to the first external terminal 41 and the first end is connected to the capacitor 30 via a third via conductor 243v. The third via conductor 243v is a via conductor existing closest to the second end surface 10e2 side of the glass substrate 10 and has only a pad portion. The coil 20 has a plurality of number of turns.

The plurality of first through conductors 23 penetrate the glass substrate 10, extend from the second coil conductor 21b toward the first coil conductor 21t, and are arranged along the axis AX.

The plurality of first coil conductors 21t are provided on the third protective layer 17.

The second through conductor 24 is provided to the side opposite to the first through conductor 23 with respect to the axis AX. The plurality of second through conductors 24 penetrate the glass substrate 10, extend from the first coil conductor 21t toward the second coil conductor 21b, and are arranged along the axis AX.

The plurality of second coil conductors 21b is provided on the second surface 10b of the glass substrate 10.

That is, a portion of the coil 20 is exposed from above the first surface 10t of the glass substrate 10, and a portion of the coil 20 is exposed from above the second surface 10b of the glass substrate 10.

The first coil conductor 21t has a shape extending in the Y direction. All the first coil conductors 21t are arranged in parallel along the X direction. The second coil conductor 21b is slightly inclined in the X direction and extends in the Y direction. All the second coil conductors 21b are arranged in parallel along the X direction.

The first through conductor 23 and the second through conductor 24 extend in directions perpendicular to the second surface 10b and the first surface 10t, respectively. All the first through conductors 23 and all the second through conductors 24 are arranged in parallel along the X direction.

The first through conductor 23 is arranged on the side of the first side surface 10s1 with respect to the axis AX in the through hole of the glass substrate 10. The first through conductor 23 is connected to the first coil conductors 21t via the first via conductor 23v penetrating the third protective layer 17. The first via conductor 23v includes a first pad portion 23v1 provided on the first through conductor 23 and a first via wiring 23v2 provided on the first pad portion 23v1 and connected to the first coil conductor 21t.

The second through conductor 24 is arranged on the side of the second side surface 10s2 with respect to the axis AX in the through hole of the glass substrate 10. The second through conductor 24 is connected to the second coil conductor 21b, and is further connected to the first coil conductor 21t via the second via conductor 24v penetrating the third protective layer 17. The second via conductor 24v includes a second pad portion provided on the second through conductor 24 and a second via wiring provided on the second pad portion and connected to the first coil conductor 21t.

The second coil conductor 21b and the first coil conductor 21t are formed of a conductive material such as copper, silver, gold, or an alloy thereof. The second coil conductor 21b and the first coil conductor 21t may be a metal film formed by plating, vapor deposition, sputtering, or the like, or may be a metal sintered body obtained by applying and sintering a conductor paste. The materials of the first through conductor 23 and the second through conductor 24 are the same as the materials of the second coil conductor 21b and the first coil conductor 21t.

The second coil conductor 21b and the first coil conductor 21t are preferably formed by a semi-additive method, whereby the second coil conductor 21b and the first coil conductor 21t having low electric resistance, high accuracy, and high aspect ratio can be formed. The first through conductor 23 and the second through conductor 24 can be formed in a through hole formed in advance in the glass substrate 10 using the materials and manufacturing methods exemplified for the second coil conductor 21b and the first coil conductor 21t.

The first via conductor 23v, the second via conductor 24v, and the third via conductor 243v can be formed by the same material and method as those of the first coil conductor.

### Capacitor 30

The capacitor 30 is provided on the first surface 10t of the glass substrate 10 and is electrically connected to the coil 20. The capacitor 30 includes the first electrode 31 and the second electrode 32 facing each other, and a dielectric film 33 arranged between the first electrode 31 and the second electrode 32. In the direction perpendicular to the axis (in the plan view), the first electrode 31 and the second electrode 32 of the capacitor 30 overlap the coil 20. With the above configuration, the size in the plane direction parallel to the axis AX can be reduced, and the electronic component 1 can be downsized. For example, in a case where the second surface 10b side of the glass substrate 10 is the mounting surface, the mounting area can be reduced.

The capacitor 30 is arranged inside the coil 20. With the above configuration, the electronic component 1 can be further downsized. The capacitor 30 may be arranged outside the coil 20.

The capacitor 30 is provided between the first coil conductor 21t and the second coil conductor 21b of the coil 20 and between the first through conductor 23 and the second through conductor 24. A portion of the capacitor 30 is arranged inside the coil 20. Note that the entire capacitor 30 may be arranged inside the coil 20.

In this specification, the “inside the coil 20” refers to a region surrounded by a surface in contact with the inner peripheries of the first through conductor 23 and the second through conductor 24 facing each other and a surface in contact with the inner peripheries of the first coil conductor 21t and the second coil conductor 21b facing each other.

The main surface of the first electrode 31 and the main surface of the second electrode 32 of the capacitor 30 are parallel to the axis AX of the coil 20. Specifically, the main surface of the first electrode 31 is parallel to the first surface 10t of the glass substrate 10, the main surface of the second electrode 32 is parallel to the first surface 10t of the glass substrate 10, and the axis AX is parallel to the first surface 10t of the glass substrate 10. With the above configuration, the axis AX of the coil 20 is parallel to the first electrode 31 and the second electrode 32 forming the capacitor 30, and the magnetic flux of the coil 20 is not hindered by the capacitor 30. As a result, the generation of the eddy current loss in the coil 20 and the capacitor 30 can be suppressed. The main surface of the first electrode 31 and the main surface of the second electrode 32 of the capacitor 30 may not be parallel to the axis AX of the coil 20.

The dielectric film 33 of the capacitor 30 completely covers the first electrode 31. Such a configuration prevents contact between the first electrode 31 and the second electrode 32. The dielectric film 33 of the capacitor 30 may not completely cover the first electrode 31.

The second electrode 32 of the capacitor 30 is electrically connected to the first coil conductor 21t of the coil 20. Specifically, the second electrode 32 of the capacitor 30 is connected to the first coil conductor 21t via the third via conductor 243v.

The first electrode 31 of the capacitor 30 is provided on the first surface 10t of the glass substrate 10 and is connected to a lead conductor 34, and the lead conductor 34 is connected to the second external terminal 42 via a fourth via conductor 34v. The fourth via conductor 34v includes a fourth pad portion 34v1 provided on the lead conductor 34 and a fourth via wiring 34v2 provided on the fourth pad portion 34v1. The lead conductor 34 and the third via conductor 243v are separated in a direction perpendicular to the axis AX, that is, in a plan view.

The materials of the first electrode 31 and the second electrode 32 are the same as the materials of the first coil conductor 21t and the second coil conductor 21b.

### First Protective Layer 15, Second Protective Layer 16, and Third Protective Layer 17

The third protective layer 17 is provided on the first surface 10t of the glass substrate 10 and covers the first surface 10t of the glass substrate 10 and the capacitor 30. The third protective layer 17 covers the capacitor 30 to protect the capacitor 30 from external force and prevent damage to the capacitor 30.

The first protective layer 15 is provided on the third protective layer 17 and covers the third protective layer 17 and the first coil conductors 21t. The first protective layer 15 covers the first coil conductors 21t to protect the first coil conductors 21t from external force and prevent damage to the first coil conductors 21t.

The second protective layer 16 is provided on the second surface 10b of the glass substrate 10 and covers the second surface 10b of the glass substrate 10 and the second coil conductors 21b. The second protective layer 16 covers the second coil conductors 21b to protect the second coil conductors 21b from external force and prevent damage to the second coil conductors 21b.

The first protective layer 15, the second protective layer 16, and the third protective layer 17 have insulating properties, and are formed of, for example, a resin such as epoxy or polyimide.

### First External Terminal 41 and Second External Terminal 42

The first external terminal 41 is provided on the second protective layer 16 on the side of the first end surface 10e1 with respect to the center of the glass substrate 10 in the X direction. The second external terminal 42 is provided on the second protective layer 16 on the side of the second end surface 10e2 with respect to the center of the glass substrate 10 in the X direction.

The first external terminal 41 is connected to the second end of the coil 20. Specifically, the first external terminal 41 is electrically connected to the first through conductor 23. That is, the first external terminal 41 is connected to the first through conductor 23 via the first via conductor 23v embedded in the second protective layer 16.

The second external terminal 42 is electrically connected to the first electrode 31 of the capacitor 30. Specifically, the second external terminal 42 is connected to the first electrode 31 via the fourth via conductor 34v embedded in the second protective layer 16 and the lead conductor 34.

The first external terminal 41 includes a base layer and a plating layer covering the base layer. The base layer includes a conductive material such as Ag or Cu. The plating layer includes a conductive material such as Ni, Sn, Pd, or Au. Similarly, the second external terminal 42 has a base layer and a plating layer covering the base layer. The first external terminal 41 and the second external terminal 42 may be formed of a single-layer conductive material.

### Method for Manufacturing Electronic Component 1

Next, a method for manufacturing the electronic component 1 will be described with reference to FIGS. 1, 2, and 3.

The glass substrate 10 is prepared. The glass substrate 10 is formed of, for example, photosensitive glass, and is easy to process through holes and the like. In addition, the flatness of the surface of the glass substrate 10 is desirably significantly high.

A through hole penetrating from the first surface 10t to the second surface 10b is provided in the glass substrate 10. The first through conductor 23, the second through conductor 24, and the lead conductor 34 are arranged in the through hole. Specifically, the first through conductor 23 is arranged on the side of the first side surface 10s1 with respect to the axis AX in the through hole of the glass substrate 10, the second through conductor 24 is arranged on the side of the second side surface 10s2 with respect to the axis AX in the through hole of the glass substrate 10, and the lead conductor 34 is arranged in the through hole closest to the second end surface 10e2 in the through holes of the glass substrate 10.

The first electrode 31 of the capacitor 30 is provided on the first surface 10t of the glass substrate 10 so as to be connected to the lead conductor 34. Further, the dielectric film 33 is provided on the first electrode 31, and the second electrode 32 of the capacitor 30 is provided on the dielectric film 33.

In addition, the first pad portion 23v1 connected to the first through conductor 23 and the second pad portion (not illustrated) connected to the second through conductor 24 are provided on the first surface 10t of the glass substrate 10.

The third protective layer 17 is provided so as to cover the capacitor 30, the first pad portion 23v1, and the second pad portion.

A through hole for forming a via wiring is provided in the third protective layer 17 to form the via wiring. Specifically, a through hole is formed between the first surface of the third protective layer 17 positioned on the opposite side of the glass substrate 10 and the first pad portion 23v1 to form the first via wiring 23v2. The first pad portion 23v1 and the first via wiring 23v2 are connected to form a first via conductor 23 v. Although not illustrated, a through hole is formed between the first surface of the third protective layer 17 and the second pad portion to form a second via wiring 24v2. The second pad portion and the second via wiring 24v2 are connected to form a second via conductor 24v. Further, a through hole is formed between the first surface of the third protective layer 17 and the second electrode 32 of the capacitor 30 to form the third via conductor 243v.

The first coil conductor 21t is formed on the third protective layer 17. The first coil conductor 21t connects the first via conductor 23v and the second via conductor 24v. In addition, the first coil conductor 21t connects the third via conductor 243v positioned closest to the side of the second end surface 10e2 of the glass substrate 10 and the first via conductor 23v positioned closest to the third via conductor 243v.

The first protective layer 15 is provided on the third protective layer 17 so as to cover the first coil conductor 21t.

On the other hand, the second coil conductor 21b is provided on the second surface 10b of the glass substrate 10. The second coil conductor 21b connects the first through conductor 23 and the second through conductor 24.

In addition, the fourth pad portion 34v1 is provided on the second surface 10b of the glass substrate 10 so as to be connected to the lead conductor 34.

The second protective layer 16 is provided on the second surface 10b of the glass substrate 10 so as to cover the second coil conductor 21b and the fourth pad portion 34v1.

A through hole for providing a via wiring is provided in the second protective layer 16 to form the fourth via wiring 34v2. The fourth pad portion 34v1 and the fourth via wiring 34v2 are connected to form the fourth via conductor 34v.

Further, the first external terminal 41 and the second external terminal 42 are provided to the surface of the second protective layer 16, and the surface positioned on the opposite side of the second surface 10b of the glass substrate 10. The first external terminal 41 and the second external terminal 42 are separated from each other. The first external terminal 41 is electrically connected to the end of the coil 20 on the second surface 10b of the glass substrate 10, and the second external terminal 42 is connected to the fourth via conductor 34v.

As described above, the electronic component 1 is formed.

In the first embodiment, the lead conductor 34 and the third via conductor 243v are separated from each other in plan view, but may overlap each other in plan view, for example. With the above aspect, the electronic component 1 can be downsized.

### Second Embodiment

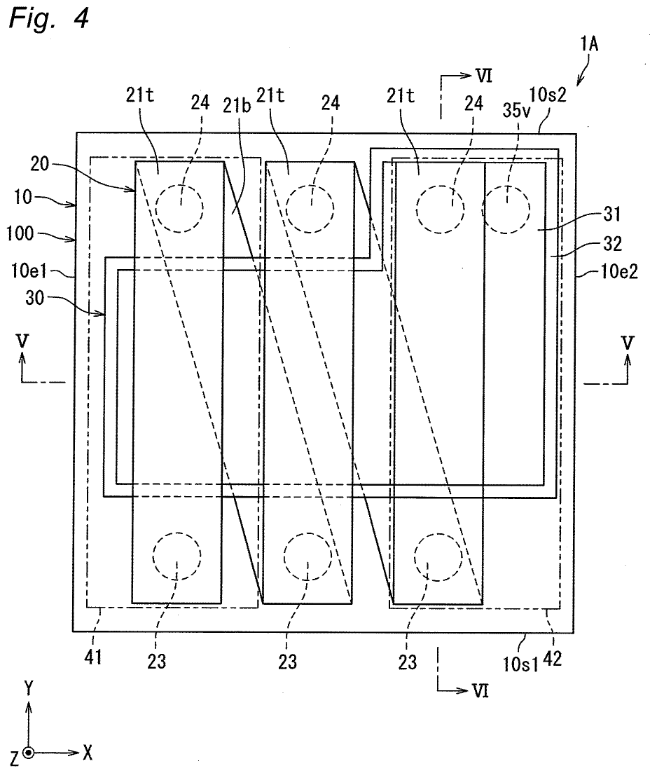

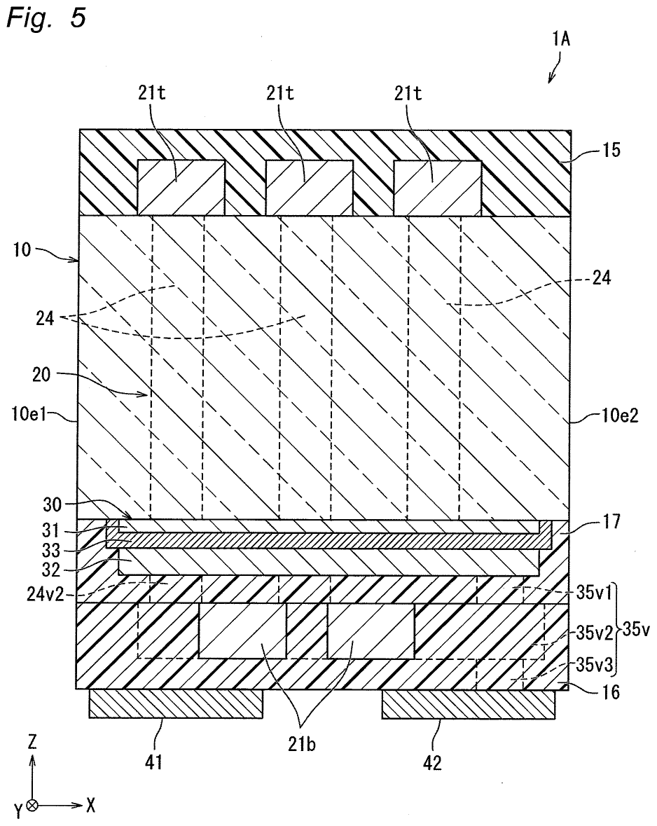

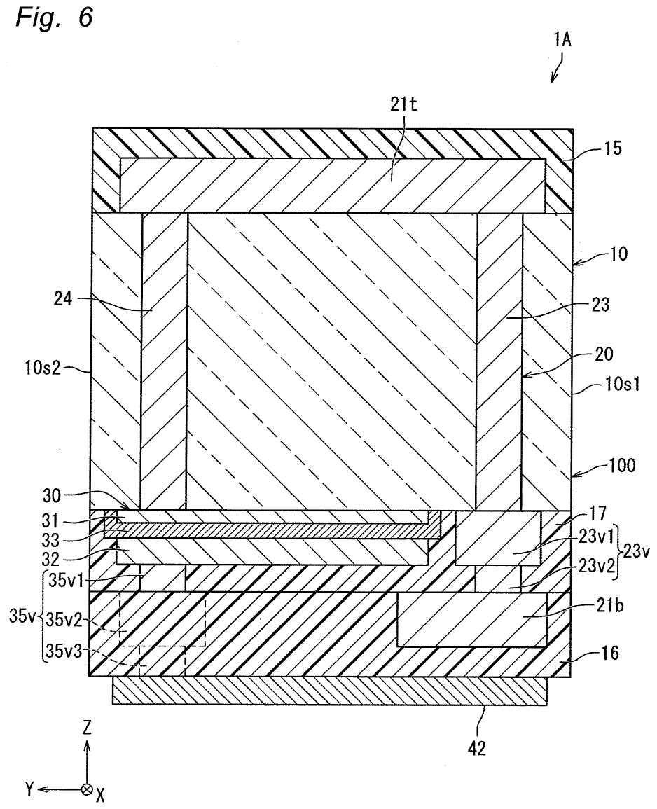

FIG. 4 shows a schematic top view of an electronic component 1A as viewed from a top surface side. FIG. 5 shows a cross-sectional view taken along line V-V of FIG. 4. FIG. 6 shows a cross-sectional view taken along line VI-VI of FIG. 4. The second embodiment is different from the first embodiment in the positions of the capacitor 30 and the third protective layer 17. This different configuration will be described below. The other configurations are the same as those of the first embodiment, and the description thereof will be omitted.

The capacitor 30 is provided on the second surface 10b of the glass substrate 10, and is electrically connected to the second external terminal 42. By providing the capacitor 30 on the side of the second external terminal 42 with respect to the glass substrate 10, in a case where the capacitor 30 is connected to the ground of the mounting substrate, the L component between the capacitor and the ground can be reduced, and as a result, deterioration of the high frequency characteristics can be suppressed. Further, in a case where the side of the second external terminal 42 is used as the mounting surface, the center of gravity of the electronic component 1A can be lowered by providing the capacitor 30 on the side of the second external terminal 42 with respect to the glass substrate 10.

Unlike the first embodiment in which the capacitor 30 is provided on the first surface 10t of the glass substrate 10, the capacitor 30 is provided on the second surface 10b of the glass substrate 10. The first electrode 31 of the capacitor 30 is provided on the second surface 10b of the glass substrate 10. The dielectric film 33 is provided to the first electrode 31 of the capacitor 30, and the second electrode 32 of the capacitor 30 is provided on the dielectric film 33. That is, the capacitor 30 includes the first electrode 31 and the second electrode 32 opposed to each other provided on the second surface 10b of the glass substrate 10, and the dielectric film 33 arranged between the first electrode 31 and the second electrode 32.

The third protective layer 17 covers the capacitor 30 and is provided on the second surface 10b of the coil 20. The first protective layer 15 is provided on the first surface 10t of the glass substrate 10. The second protective layer 16 is provided on the third protective layer 17.

Similarly to the first embodiment, the coil 20 is electrically connected to the first through conductor 23, the first coil conductor 21t, the second through conductor 24, and the second coil conductor 21b in this order to form a spiral. The first through conductor 23 and the second through conductor 24 are provided on the first surface 10t and connected to the first coil conductor 21t.

In the coil 20, the first coil conductor 21t is positioned on the first surface 10t of the glass substrate 10, and the second coil conductor 21b is positioned on the surface of the third protective layer 17 on the side opposite to the glass substrate 10.

In the coil 20, the first via conductor 23v connected to the first through conductor 23 and the second via conductor 24v connected to the second through conductor 24 are formed on the second surface 10b of the glass substrate 10. The first via conductor 23v includes the first pad portion 23v1 provided on the first through conductor 23 and the first via wiring 23v2 provided on the first pad portion 23v1, and the second via conductor 24v includes a second pad portion provided on the second via conductor 24v and the second via wiring 24v2 provided on the second pad portion.

The first protective layer 15 covers the first coil conductor 21t. The second protective layer 16 covers the second coil conductor 21b. The first via conductor 23v and the second via conductor 24v penetrate the third protective layer 17.

The second through conductor 24 provided in the through hole closest to the second end surface 10e2 of the glass substrate 10 is connected to the first electrode 31 of the capacitor 30.

The second electrode 32 of the capacitor 30 is connected to the second external terminal 42 via a fifth via wiring 35v1 penetrating the third protective layer 17, a fifth pad portion 35v2, and a fifth via wiring 35v3 penetrating the second protective layer 16. The fifth pad portion 35v2 and the fifth via wiring 35v3, and the fifth via wiring 35v3 connected to the fifth pad portion 35v2 and connected onto the second electrode 32 form a fifth via conductor 35v.

The capacitor 30 is provided between the second surface 10b of the glass substrate 10 and the second protective layer, and between the first through conductor 23 and the second through conductor 24.

### Third Embodiment

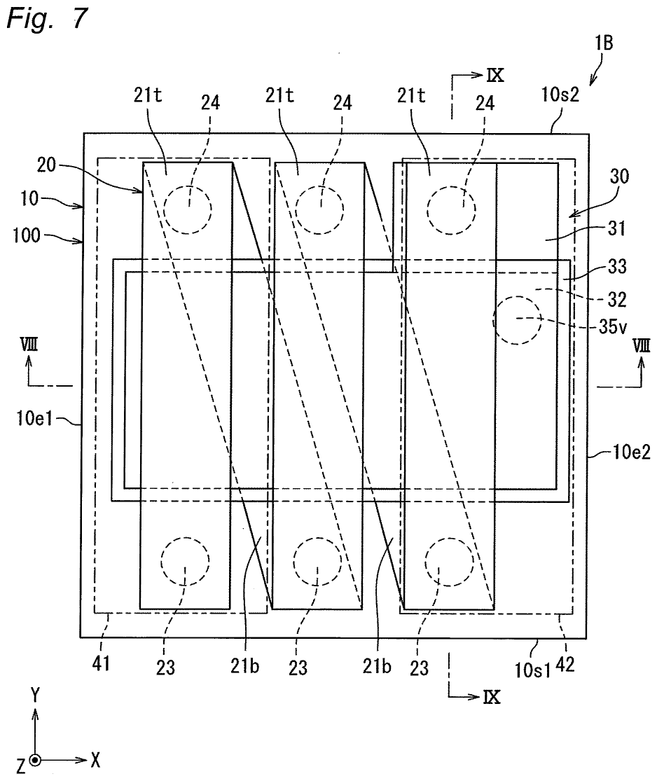

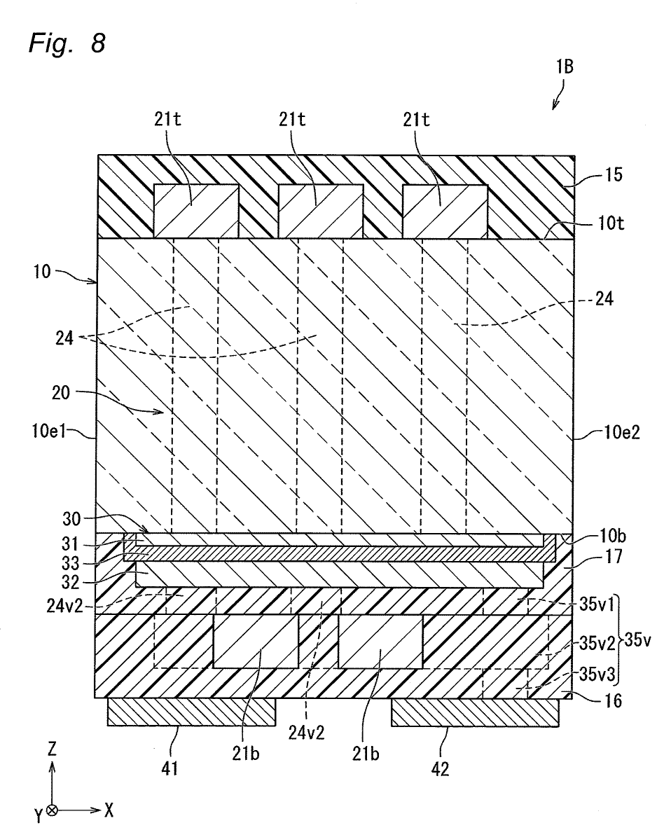

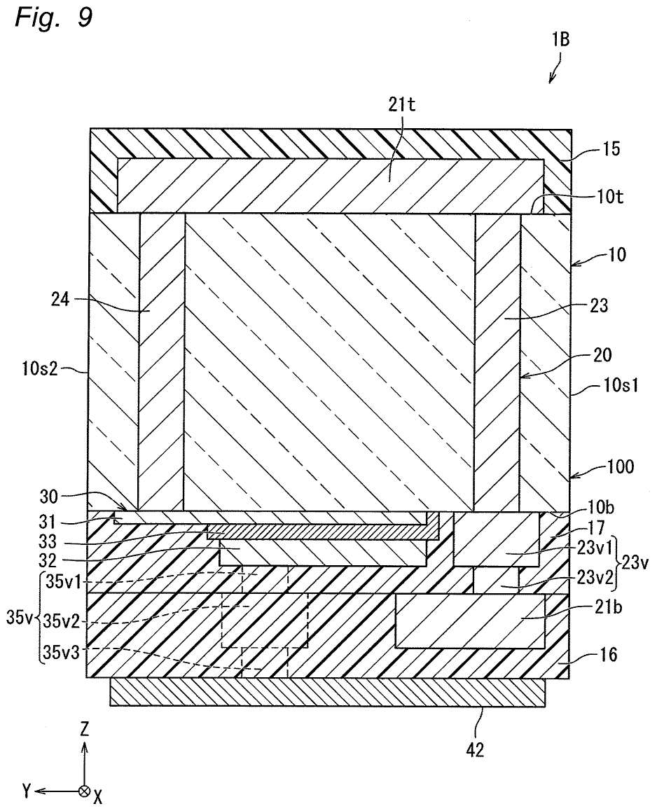

FIG. 7 shows a schematic top view of an electronic component 1B as viewed from the top surface side. FIG. 8 shows a cross-sectional view taken along line VIII-VIII of FIG. 7. FIG. 9 shows a cross-sectional view taken along line IX-IX of FIG. 7. The third embodiment is different from the second embodiment in the positions of the dielectric film 33 and the fifth via conductor 35v of the capacitor 30. This different configuration will be described below. The other configurations are the same as those of the second embodiment, and the description thereof will be omitted.

The second through conductor 24 and the dielectric film 33 are separated from each other when viewed from the direction perpendicular to the first surface 10t. With the above configuration, even if stress is generated due to a difference in linear expansion coefficient between the glass substrate 10 and the second through conductor 24 between the linear expansion coefficient of the glass substrate 10 and the linear expansion coefficient of the second through conductor 24 which is greater than the linear expansion coefficient of the glass substrate 10, it is possible to prevent the dielectric film 33 from being damaged. As a result, the reliability of the electronic component 1B is improved.

The first electrode 31 of the capacitor 30 is provided on the second surface 10b of the glass substrate 10. Unlike the second embodiment, the first electrode 31 of the capacitor 30 has a surface not in contact with the dielectric film 33 or the second electrode 32. The first electrode 31 has a surface that does not overlap the dielectric film 33 or the second electrode 32 on a surface opposite to the second surface 10b of the glass substrate 10. Specifically, as illustrated in FIG. 9, the first electrode 31 does not include the dielectric film 33 or the second electrode 32 on the extension of the second through conductor 24. Furthermore, in plan view, the position of the second through conductor 24 and the position of the second electrode 32 are separated from each other. With such a configuration, the dielectric film 33 and the second electrode 32 can be downsized, and the material to be used can be reduced. Further, the position of the fifth via conductor 35v and the position of the second through conductor 24 are separated from each other.

### Fourth Embodiment

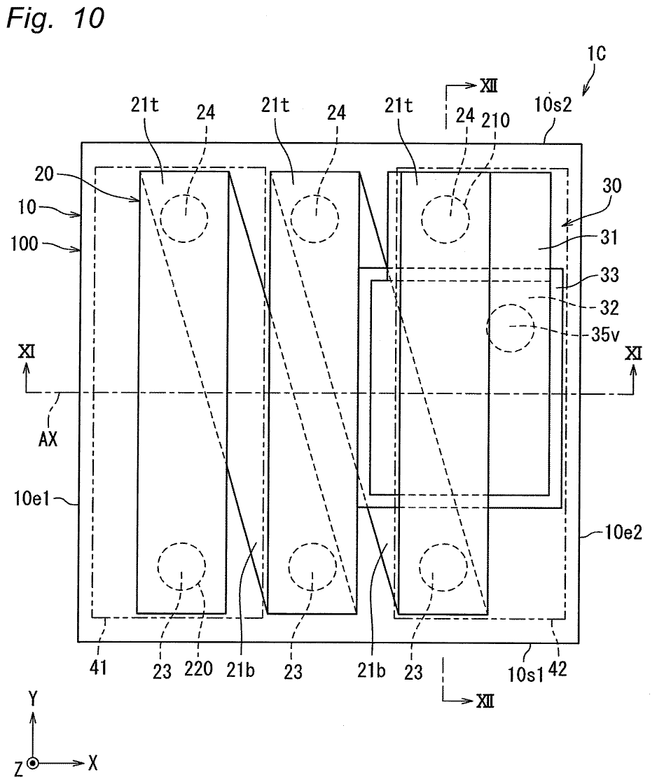

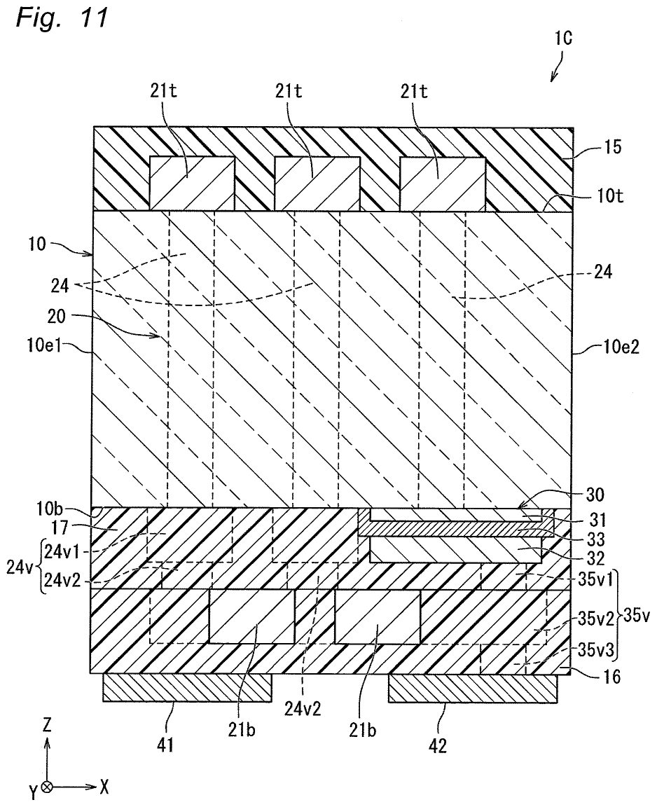

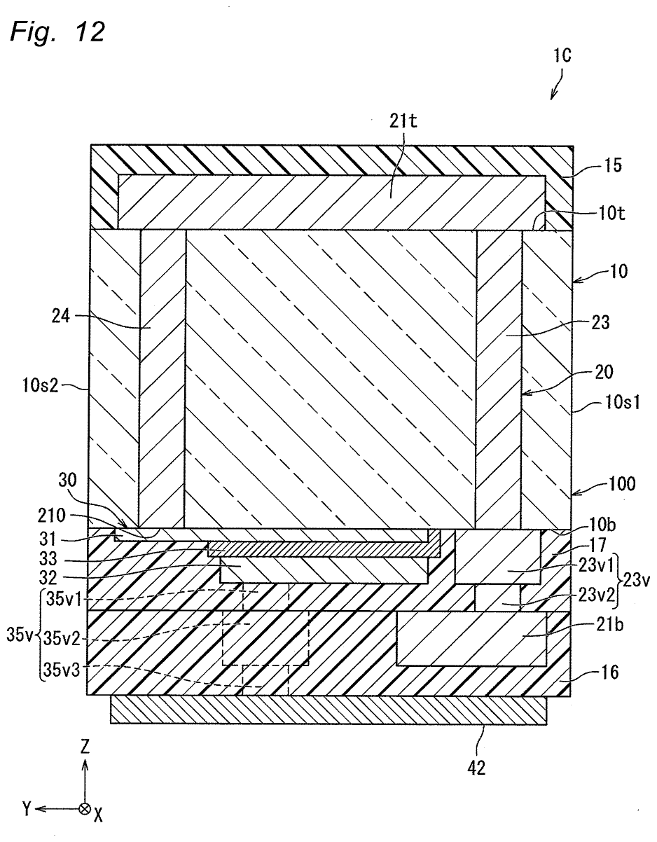

FIG. 10 shows a schematic top view of an electronic component 1C as viewed from the top surface side. FIG. 11 shows a cross-sectional view taken along line XI-XI of FIG. 10. FIG. 12 shows a cross-sectional view taken along line XII-XII of FIG. 10. The fourth embodiment is different from the third embodiment in the position of the capacitor 30. This different configuration will be described below. The other configurations are the same as those of the third embodiment, and the description thereof will be omitted.

The coil 20 has a first end 210 and a second end 220. The first end 210 is connected to the first electrode 31 of the capacitor 30. The second end 220 is connected to a via conductor (not illustrated) penetrating the second protective layer 16 and the third protective layer 17. The first end 210 is an end of the second through conductor 24 connected to the first electrode 31. The second end 220 is an end of the first through conductor 23 connected to a via conductor (not illustrated).

The capacitor 30 is positioned closer to the side of the first end 210 than to the side of the second end 220. That is, the coil 20 is positioned on the side of the second end surface 10e2 in the plan view. With the above configuration, the parasitic capacitance between the wiring of the coil 20 (the second coil conductor 21b in this embodiment) and the capacitor 30 can be effectively reduced, and the degradation of the Q value of the coil 20 due to the parasitic capacitance can be suppressed.

“Positioned closer to the side of the first end 210 than the side of the second end 220” means that, as shown in FIG. 10 (in plan view), it passes through the center of the coil 20 on the axis AX of the coil 20 and is positioned closer to the side of the second end surface 10e2 than a plane perpendicular to the axis AX of the coil 20. Note that the capacitor 30 may be positioned closer to the side of the second end surface 10e2 than the side of the first end surface 10e1, with respect to a plane passing through the center of the coil 20 on the axis AX of the coil 20 and perpendicular to the axis AX of the coil 20.

### Fifth Embodiment

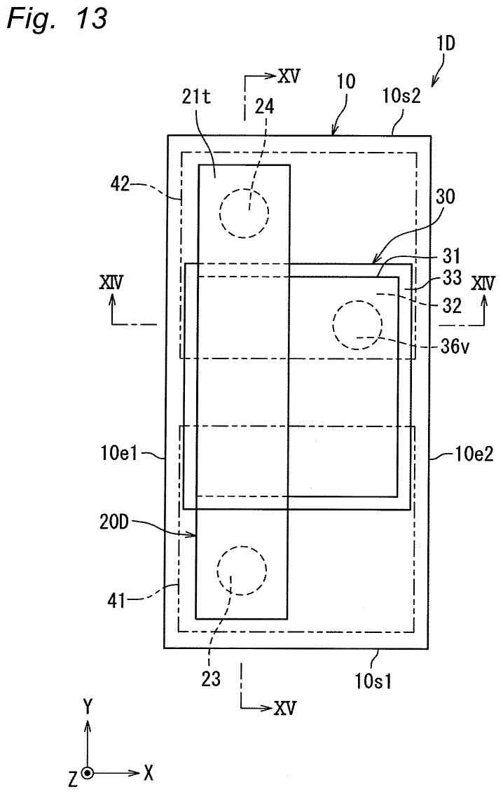

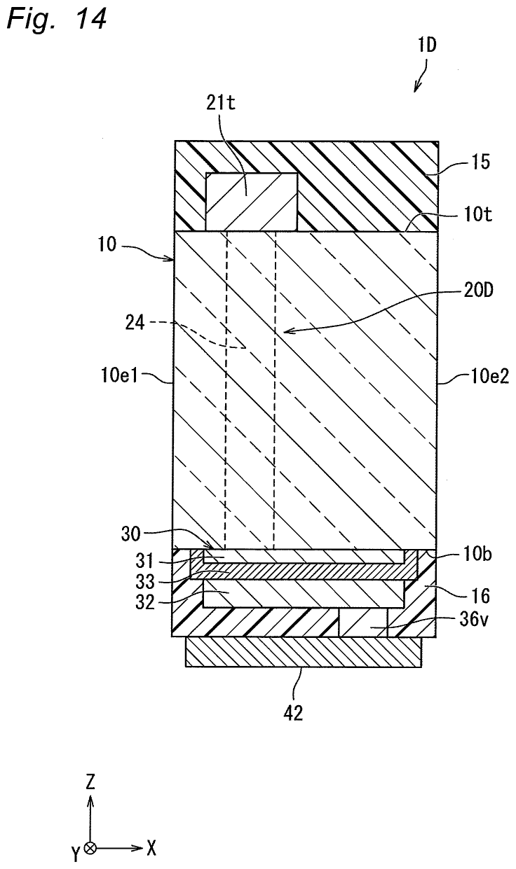

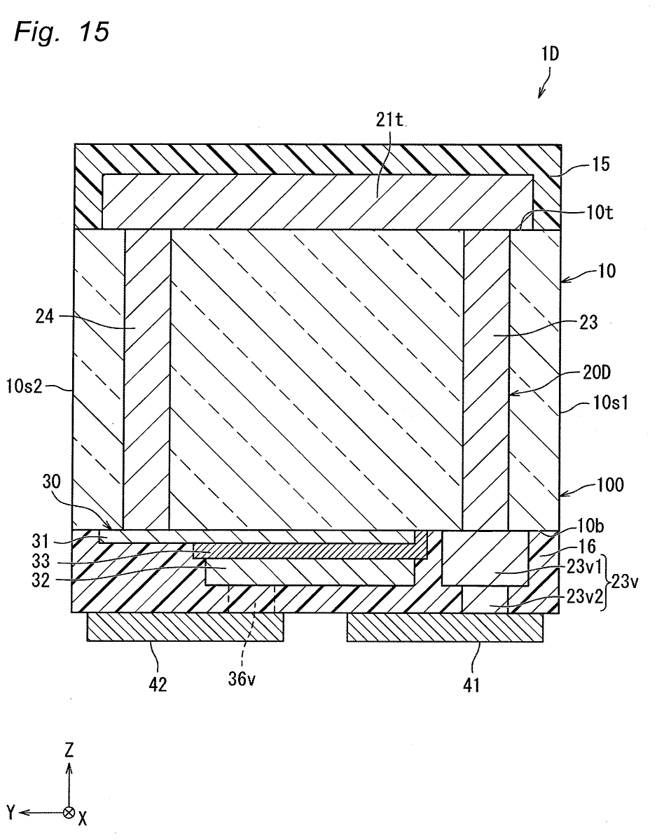

FIG. 13 shows a schematic top view of an electronic component 1D as viewed from the top surface side. FIG. 14 shows a cross-sectional view taken along line XIV-XIV of FIG. 13. FIG. 15 shows a cross-sectional view taken along line XV-XV of FIG. 13. The fifth embodiment is different from the third embodiment in the number of turns of a coil 20D and the form of the capacitor 30, and the fifth embodiment does not include the third protective layer 17. This different configuration will be described below. The other configurations are the same as those of the third embodiment, and the description thereof will be omitted.

The number of turns of the coil 20D is less than 1 turn. The coil 20D includes the first through conductor 23 penetrating the glass substrate 10 from the second surface 10b toward the first surface 10t, the first coil conductor 21t connected to the first through conductor 23 and provided on the glass substrate 10, and the second through conductor 24 connected to the first coil conductor 21t and penetrating the glass substrate 10 from the first surface 10t toward the second surface 10b. The capacitor 30 is provided on the second surface 10b of the glass substrate 10 and is connected to the second through conductor 24. With the above configuration, the wiring of the coil 20D (the first external terminal 41 in this embodiment) is reduced, and the manufacturing cost can be reduced.

The coil 20D does not include the second coil conductor 21b of the third embodiment.

The first through conductor 23 of the coil 20D is connected to the first via conductor 23v. The first via conductor 23v includes the first pad portion 23v1 connected to the first through conductor 23 and the first via wiring 23v2 connected to the first pad portion 23v1.

The capacitor 30 is not positioned inside the coil 20D. Specifically, the capacitor 30 is not positioned between the first coil conductor 21t and the second coil conductor 21b, and is not positioned between the first through conductor 23 and the second through conductor 24.

The first electrode 31 of the capacitor 30 has a notch at a corner on the side where the second end surface 10e2 and the second side surface 10s2 intersect in plan view. The first electrode 31 has a portion overlapping the second through conductor 24. The second electrode 32 and the dielectric film 33 are positioned between the first through conductor 23 and the second through conductor 24, and do not overlap the second through conductor 24. With the above configuration, the material to be used can be reduced. Note that the first electrode 31 of the capacitor 30 may have a rectangular shape having the same length as the length in the X direction of the region passing between the first through conductor 23 and the second through conductor 24 in plan view.

The capacitor 30 is connected to the second through conductor 24 at the first electrode 31, and is connected to a sixth via conductor 36v at the second electrode 32. In plan view, the second through conductor 24 and the sixth via conductor 36v are separated from each other.

The second protective layer 16 is provided on the second surface 10b of the glass substrate 10 and covers the capacitor 30. The first via conductor 23v and the sixth via conductor 36v penetrate the second protective layer 16.

### Sixth Embodiment

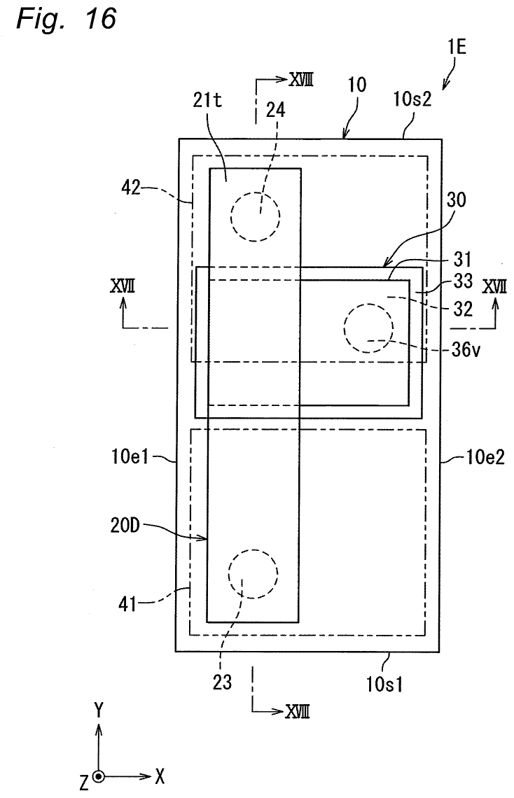

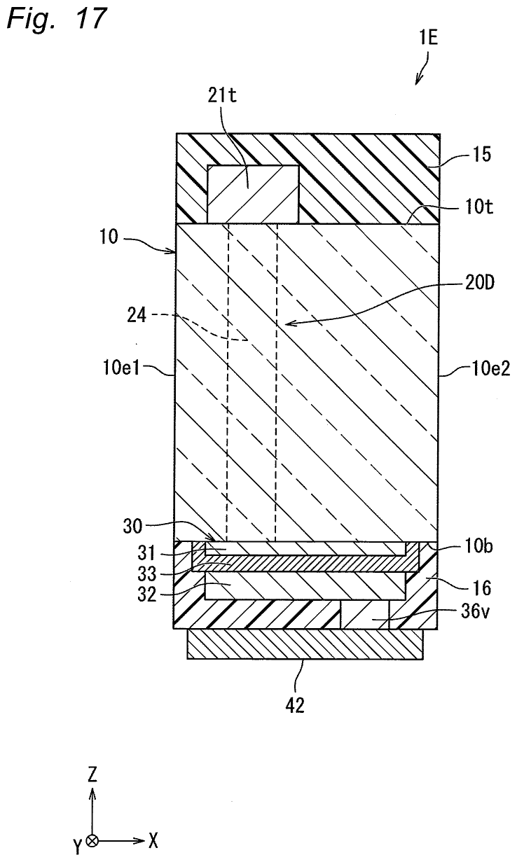

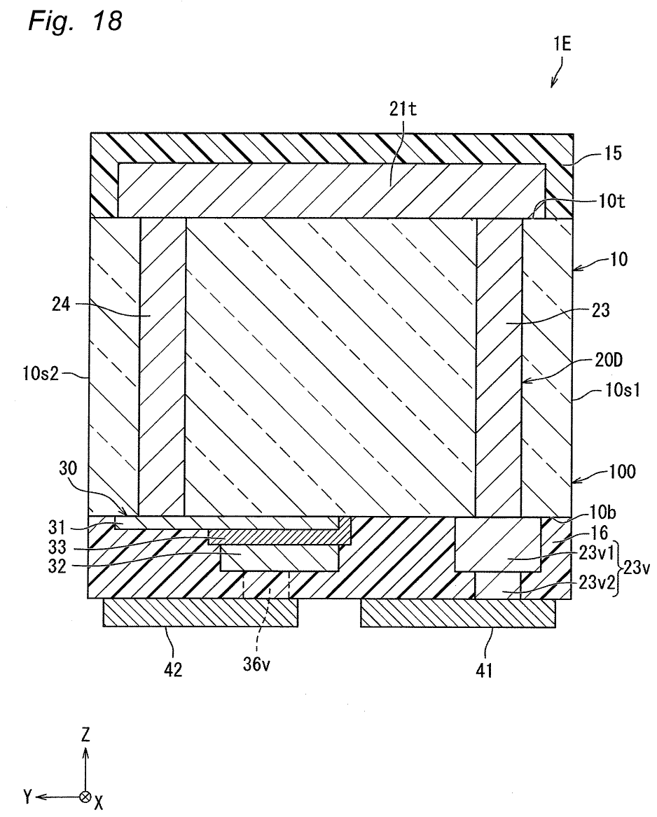

FIG. 16 shows a schematic top view of an electronic component 1E as viewed from the top surface side. FIG. 17 shows a cross-sectional view taken along line XVII-XVII of FIG. 16. FIG. 18 shows a cross-sectional view taken along line XVIII-XVIII of FIG. 16. The sixth embodiment is different from the fifth embodiment in the form of the capacitor 30. This different configuration will be described below. The other configurations are the same as those of the fifth embodiment, and the description thereof will be omitted.

In the present embodiment, the capacitor 30 is arranged closer to the second external terminal 42 than the first external terminal 41. Specifically, the capacitor 30 is closer to the second external terminal 42 than the center line between the first external terminal 41 and the second external terminal 42 in plan view. The capacitor 30 may be positioned on the side of the first outer conductor with reference to a surface passing through the center line between the first external terminal 41 and the second external terminal 42.

Specifically, the second protective layer 16 provided on the second surface 10b of the glass substrate 10 and covering the capacitor 30, and the first external terminal 41 and the second external terminal 42 provided on the second protective layer 16 are added to the configuration of the fifth embodiment. The first external terminal 41 and the coil 20D are connected via the first via conductor 23v penetrating the third protective layer 17. The second external terminal 42 and the capacitor 30 are connected via the sixth via conductor 36v penetrating the third protective layer 17. The capacitor 30 is arranged closer to the second external terminal 42 than the first external terminal 41. With the above configuration, the parasitic capacitance between the first external terminal 41 and the capacitor 30 can be reduced, and the degradation of the Q factor of the coil 20D due to the parasitic capacitance can be suppressed.

Note that the sixth via conductor 36v of the present embodiment is an example of a second via conductor described in the claims.

### Seventh Embodiment

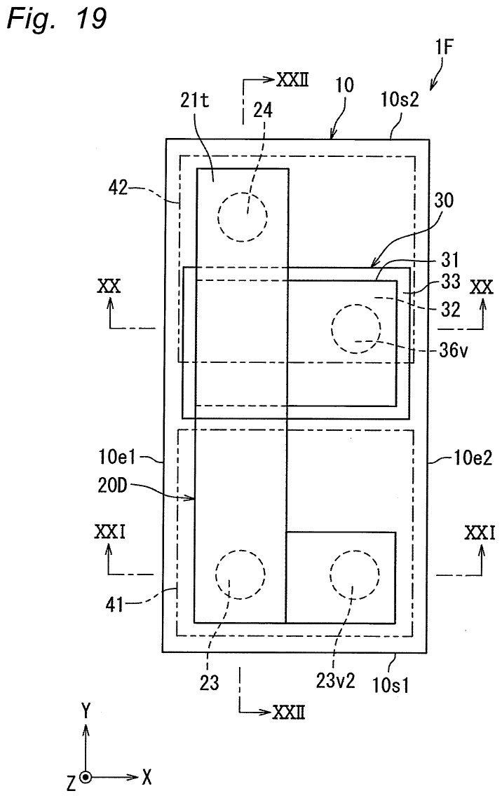

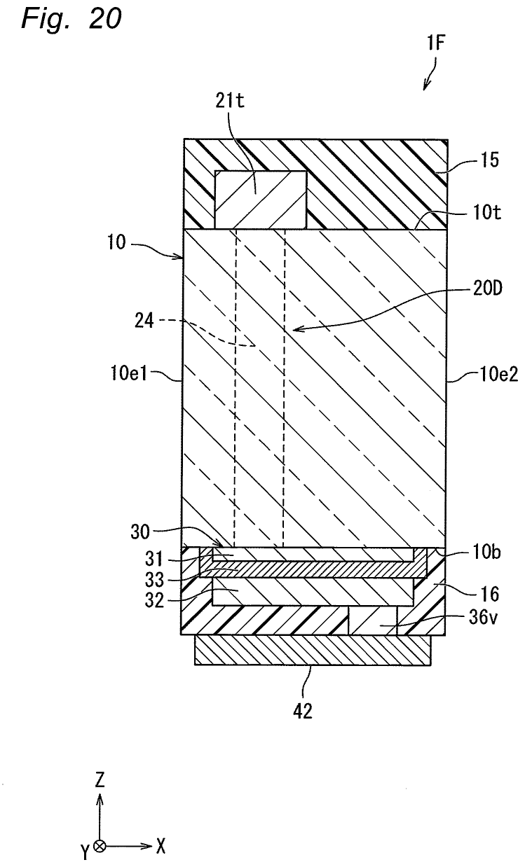

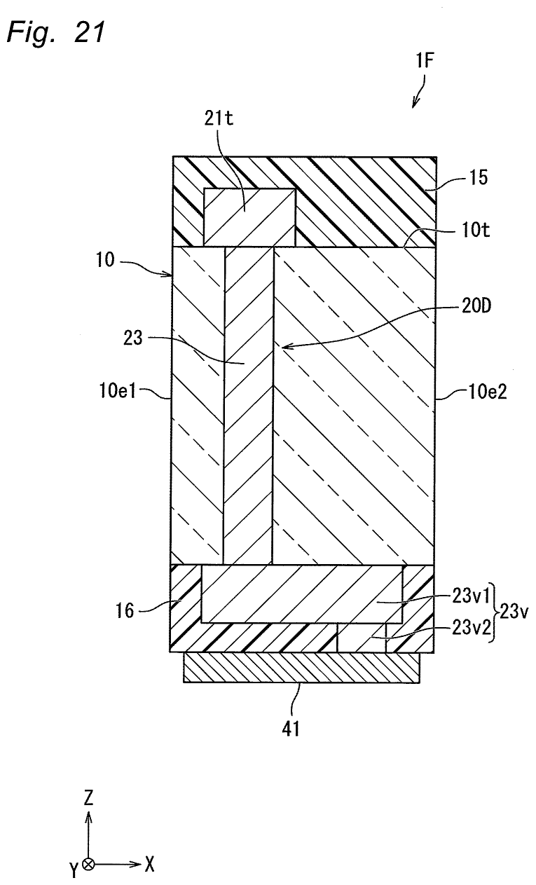

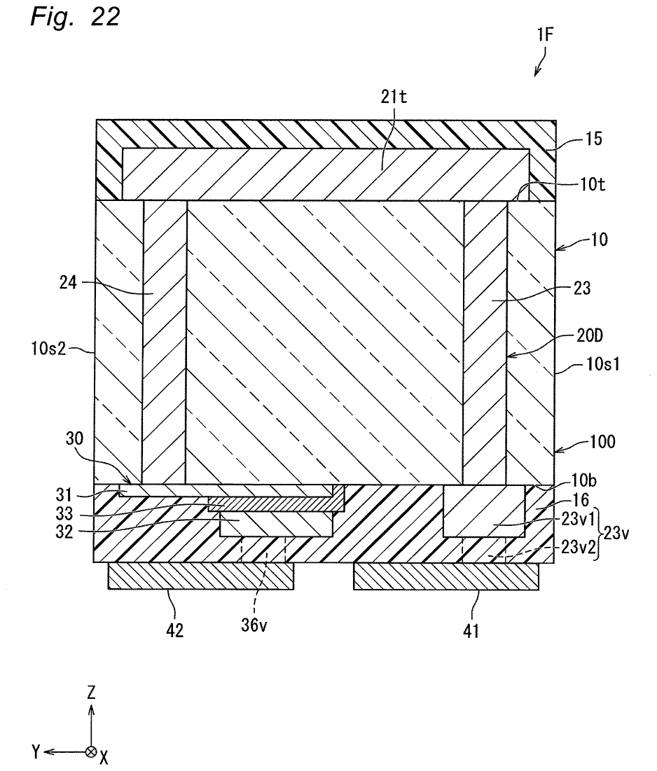

FIG. 19 shows a schematic top view of an electronic component 1F as viewed from the top surface side. FIG. 20 shows a cross-sectional view taken along line XX-XX of FIG. 19. FIG. 21 shows a cross-sectional view taken along line XXI-XXI of FIG. 19. FIG. 22 shows a cross-sectional view taken along line XXII-XXII of FIG. 19. The seventh embodiment is different from the sixth embodiment in the position of the first via conductor 23v. This different configuration will be described below. The other configurations are the same as those of the sixth embodiment, and the description thereof will be omitted.

The first via conductor 23v includes the first pad portion 23v1 connected to the first through conductor 23 and the first via wiring 23v2 connected to the first pad portion 23v1 and the first external terminal 41. When viewed from the direction perpendicular to the first surface 10t, the first through conductor 23 and the first via wiring 23v2 are separated from each other. With the above configuration, even if stress is generated due to the difference in linear expansion coefficient between the glass substrate 10 and the first through conductor 23, it is possible to prevent the first via wiring 23v2 from being damaged. As a result, the reliability of the electronic component 1F is improved.

Note that the first via conductor 23v of the present embodiment is an example of a first via conductor described in the claims. The first pad portion 23v1 is an example of a pad portion described in the claims. The first via wiring 23v2 is an example of a via portion described in the claims.

### Eighth Embodiment

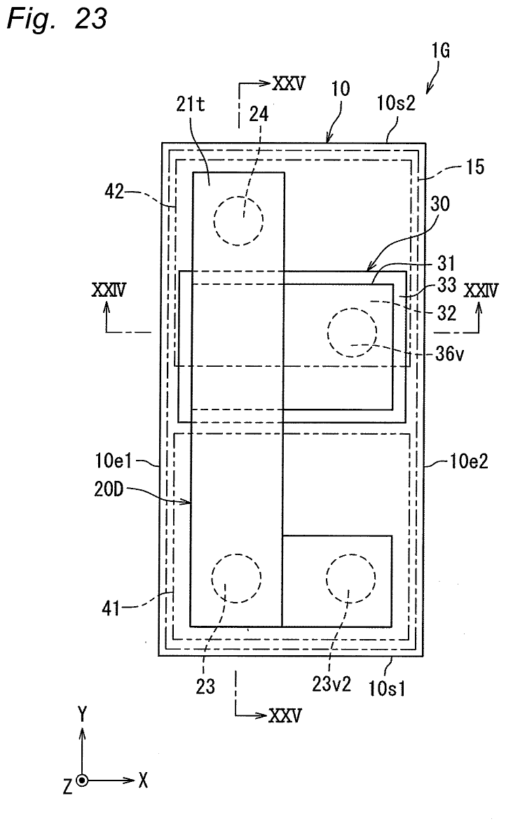

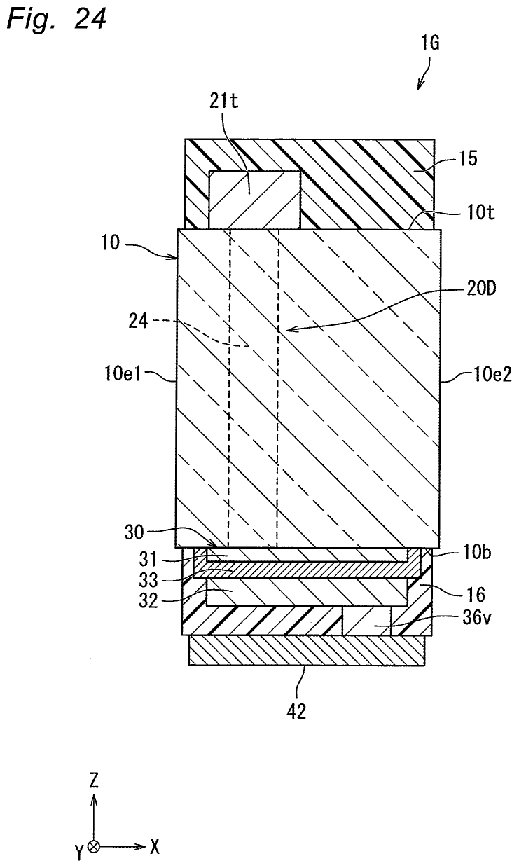

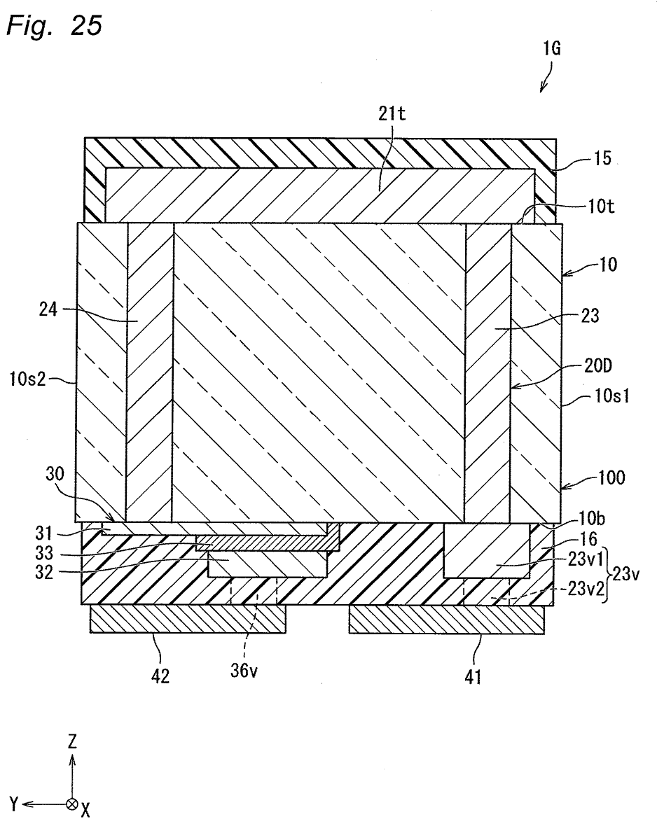

FIG. 23 shows a schematic top view of an electronic component 1G as viewed from the top surface side. FIG. 24 shows a cross-sectional view taken along line XXIV-XXIV of FIG. 23. FIG. 25 shows a cross-sectional view taken along line XXV-XXV of FIG. 23. The eighth embodiment is different from the seventh embodiment in the sizes of the first protective layer 15 and the second protective layer 16. This different configuration will be described below. In FIG. 23, the first protective layer 15 is indicated by a one-dot chain line. The other configurations are the same as those of the seventh embodiment, and the description thereof will be omitted.

When viewed from the direction perpendicular to the first surface 10t of the glass substrate 10, the first protective layer 15 is positioned inside the outer periphery of the first surface 10t of the glass substrate 10. When viewed from the direction perpendicular to the second surface 10b, the second protective layer 16 is positioned inside the outer periphery of the second surface 10b of the glass substrate 10. Specifically, as illustrated in FIG. 23, the area of the first protective layer 15 is smaller than the area of the glass substrate 10 in the direction perpendicular to the axis AX. Although not illustrated in FIG. 23, the area of the second protective layer 16 is similarly smaller than the area of the glass substrate 10. With the above configuration, processing of the glass substrate 10 is facilitated. For example, when the glass substrate 10 is cut, a portion of the glass substrate 10 to be cut can be crystallized and cut by etching. In addition, for example, in the case of cutting with a dicer, it is possible to prevent the first protective layer 15 and the second protective layer 16 from being peeled off from the glass substrate 10 due to a load of the dicer.

When viewed from a direction perpendicular to the first surface 10t, the outer periphery of the first protective layer 15 preferably has a shape along the outer periphery of the glass substrate 10. The outer periphery of the second protective layer 16 preferably has a shape along the outer periphery of the glass substrate 10.

### Ninth Embodiment

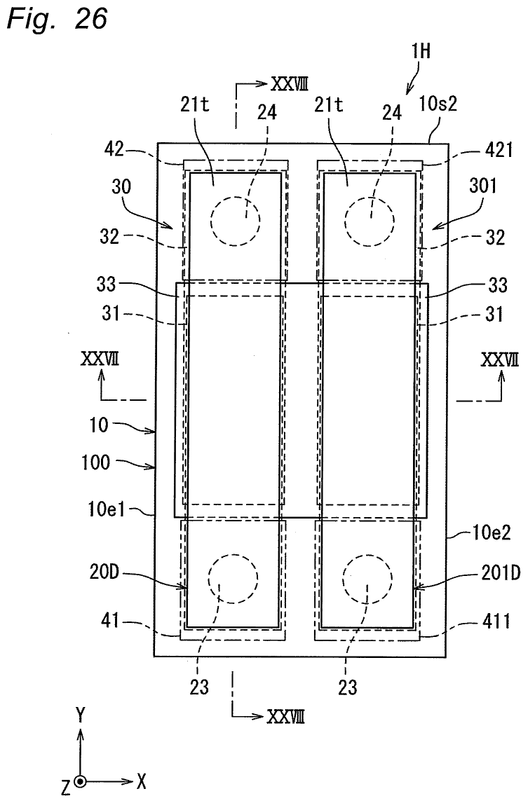

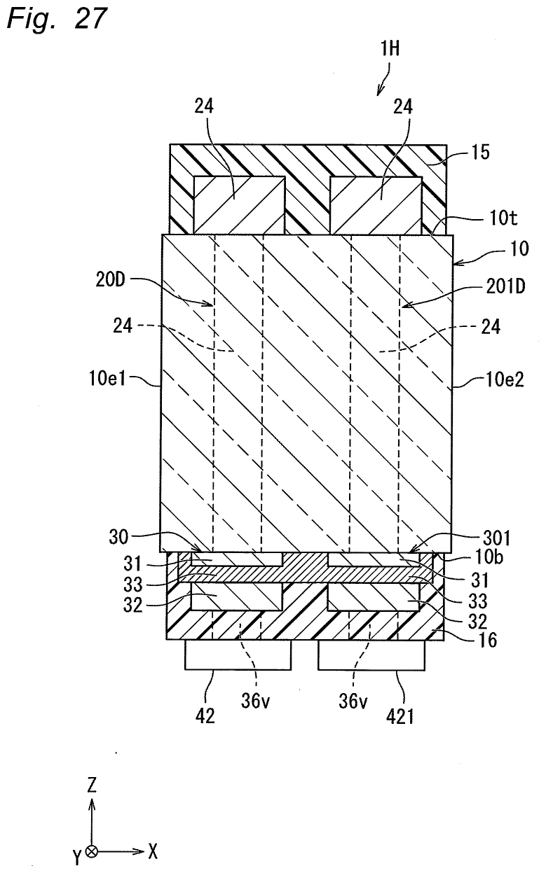

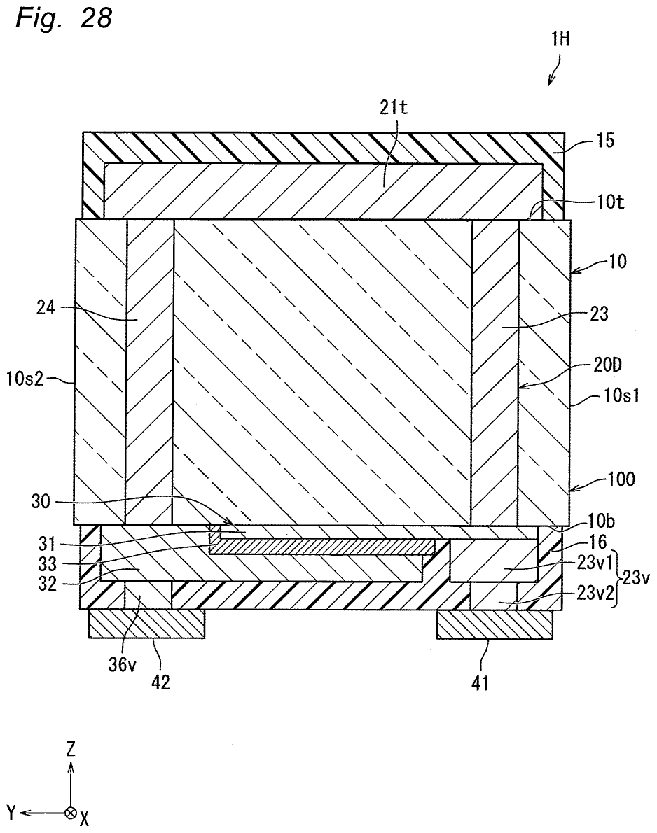

FIG. 26 shows a schematic top view of an electronic component 1H as viewed from the top surface side. FIG. 27 shows a cross-sectional view taken along line XXVII-XXVII of FIG. 26. FIG. 28 shows a cross-sectional view taken along line XXVIII-XXVIII of FIG. 26. In the ninth embodiment, unlike the fifth embodiment, the coil 20D and a coil 201D, and the capacitor 30 and a capacitor 301 are connected in parallel. Furthermore, the ninth embodiment is different from the fifth embodiment in the position of the sixth via conductor 36v, the number of coils, the number of capacitors, and the number of external terminals. This different configuration will be described below. The other configurations are the same as those of the fifth embodiment, and the description thereof will be omitted.

In the present embodiment, as illustrated in FIG. 26, two coils 20D and 201D, two capacitors 30 and 301, and four external terminals 41, 411, 42, and 421 are provided. That is, the electronic component 1H includes a plurality of coils and capacitors. With the above configuration, the number of elements can be increased, and the effect of reducing the mounting area is increased. As a result, further downsizing of the electronic component 1H becomes remarkable. A plurality of at least one of the coil and the capacitor may be provided.

The first electrode 31 of the capacitor 30 is connected to the first through conductor 23 of the coil 20D. The second electrode 32 of the capacitor 30 is connected to the second through conductor 24 of the coil 20D.

The first electrode 31 of the capacitor 30 is connected to the first external terminal 41 via the first via conductor 23v. The second electrode 32 of the capacitor 30 is connected to the second external terminal 42 via the sixth via conductor 36v.

The sixth via conductor 36v is positioned at a position overlapping the second through conductor 24 when viewed from the direction perpendicular to the first surface 10t.

The capacitor 301 has the same configuration as the capacitor 30. Specifically, the first electrode 31 of the capacitor 301 is connected to the first through conductor 23 of the coil 201D. The second electrode 32 of the capacitor 301 is connected to the second through conductor 24 of the coil 201D. The first electrode 31 of the capacitor 301 is connected to the first external terminal 41 via the first via conductor 23v. The second electrode 32 of the capacitor 30 is connected to the second external terminal 421 via the sixth via conductor 36v. The sixth via conductor 36v is positioned at a position overlapping the second through conductor 24 when viewed from the direction perpendicular to the first surface 10t.

The dielectric film 33 of the capacitor 30 and the dielectric film 33 of the capacitor 301 are common members. That is, the dielectric film 33 is positioned to extend inside both the coils 20D and 201D. Note that the dielectric film 33 of the capacitor 30 and the dielectric film 33 of the capacitor 301 may be provided separately.

Although the coil 20D and the coil 201D are less than one turn, they may have a plurality of turns.

### Tenth Embodiment

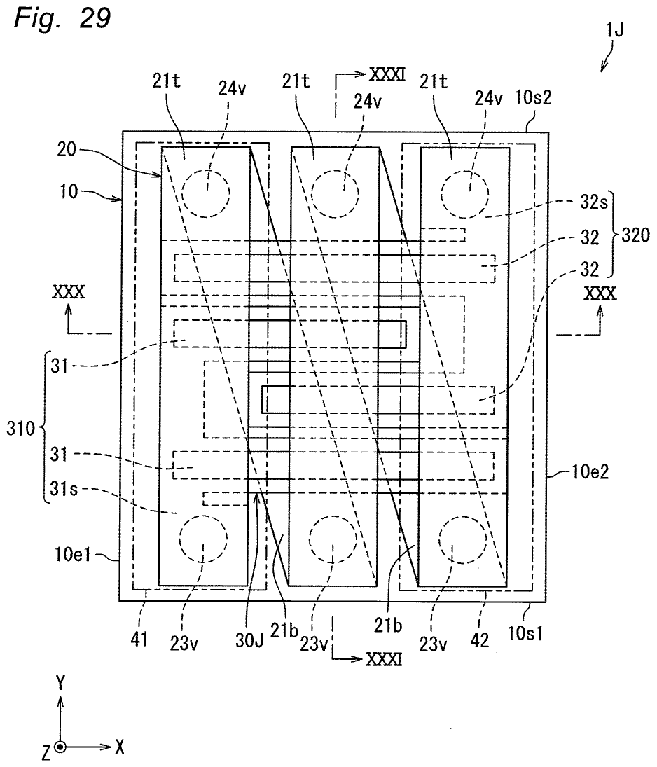

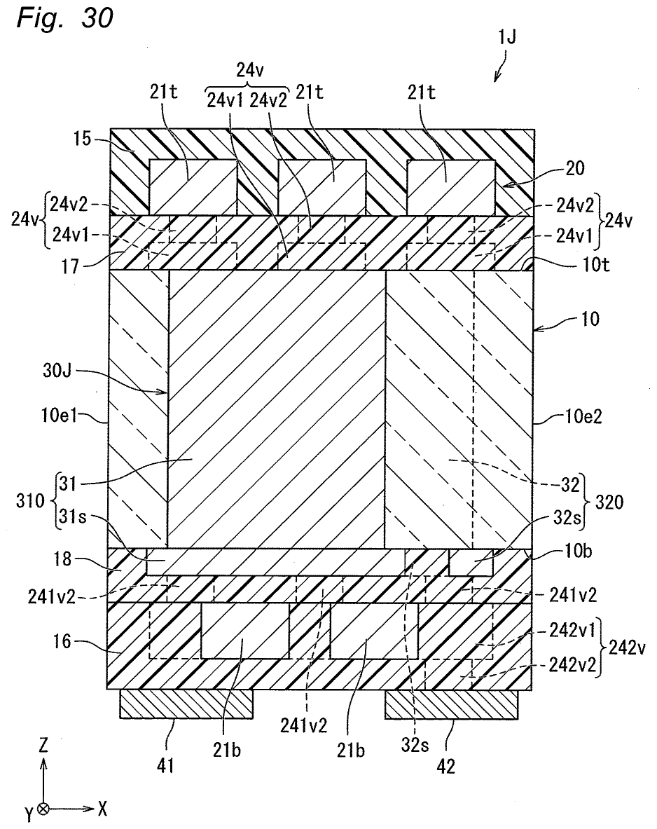

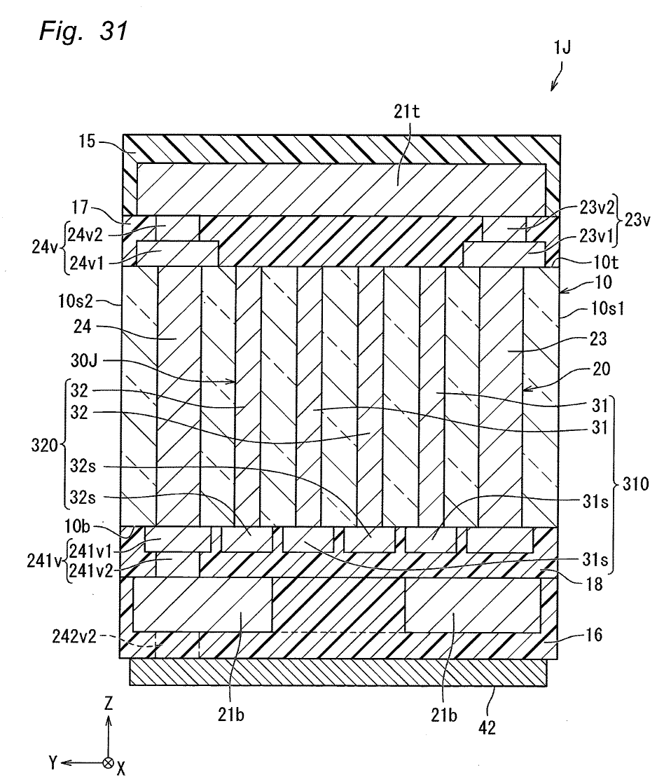

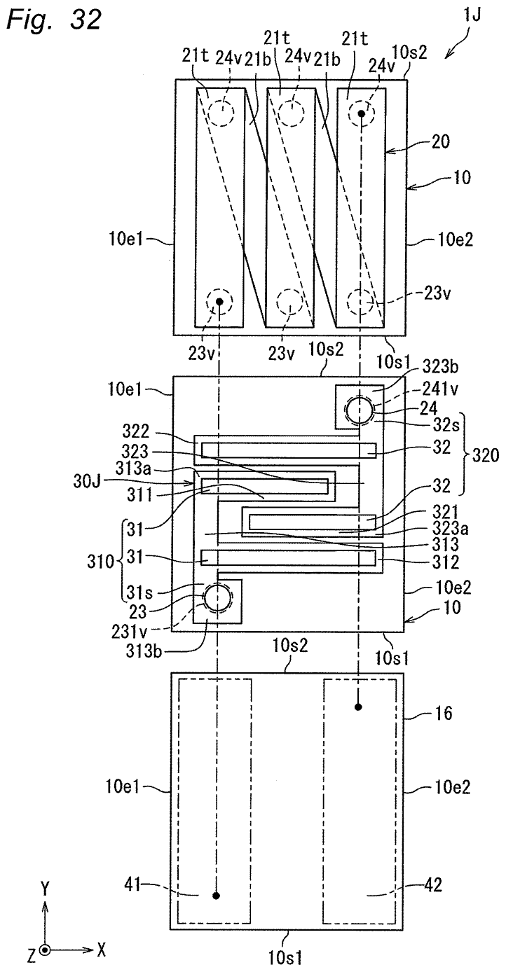

FIG. 29 shows a schematic top view of an electronic component 1J as viewed from the top surface side. FIG. 30 shows a cross-sectional view taken along line XXX-XXX of FIG. 29. FIG. 31 shows a cross-sectional view taken along line XXXI-XXXI of FIG. 29. FIG. 32 is an exploded plan view of FIG. 29. The tenth embodiment is different from the first embodiment in the structure and position of the capacitor 30J and the presence of the fourth protective layer 18. This different configuration will be described below. The other configurations are the same as those of the first embodiment, and the description thereof will be omitted.

A portion of the capacitor 30J is embedded in the glass substrate 10. The first electrode 31 and the second electrode 32 are embedded in the glass substrate 10. The glass substrate 10 is positioned between the first electrode 31 and the second electrode 32. With the above configuration, the electronic component 1J can be further downsized. In addition, the dielectric film 33 of the capacitor 30J is formed of glass, and higher reliability can be obtained for the electronic component. In addition, since it is not necessary to provide the dielectric film 33 generally used in the capacitor 30J, the electronic component 1J can be manufactured at a lower cost.

The capacitor 30J includes a first electrode unit 310 and a second electrode unit 320. Each of the first electrode unit 310 and the second electrode unit 320 has a comb structure.

The first electrode unit 310 includes a first support portion 31s and a plurality of first electrodes 31 provided on the first support portion 31s.

The first support portion 31s includes a base portion 313 positioned on the second surface 10b of the glass substrate 10 and extending along the first end surface 10e1 in the direction from the first side surface 10s1 to the second side surface 10s2, and two tooth portions 311 and 312 extending from the base portion 313 in the direction from the first end surface 10e1 to the second end surface 10e2. The first tooth portion 311 is provided at a first end 313a of the base portion 313, and the second tooth portion 312 is provided at the center of the base portion 313. One electrode is provided to one tooth portion.

One first electrode 31 is formed on the first tooth portion 311, and another first electrode 31 is provided to the second tooth portion 312. The first tooth portion 311 and the second tooth portion 312 penetrate the glass substrate 10 in the direction from the first surface 10t to the second surface 10b.

The second electrode unit 320 includes a second support portion 32s and a plurality of second electrodes 32 provided on the second support portion 32s.

The second support portion 32s includes a base portion 323 positioned on the second surface 10b of the glass substrate 10 and extending along the second end surface 10e2 in the direction from the second side surface 10s2 to the first side surface 10s1, and two tooth portions 321 and 322 extending from the base portion 323 in the direction from the second end surface 10e2 to the first end surface 10e1. The first tooth portion 321 is provided at the first end 323a of the base portion 323, and the second tooth portion 322 is provided at the center of the base portion 323. One electrode is provided to one tooth portion.

One second electrode 32 is formed on the first tooth portion 321, and another second electrode 32 is provided to the second tooth portion 322. The first tooth portion 321 and the second tooth portion 322 penetrate the glass substrate 10 in the direction from the first surface 10t to the second surface 10b.

Along the direction from the first side surface 10s1 to the second side surface 10s2 of the glass substrate 10, the second tooth portion 312 of the first support portion 31s, the first tooth portion 321 of the second support portion 32s, the first tooth portion 311 of the first support portion 31s, and the second tooth portion 322 of the second support portion 32s are arranged in this order. The number of the tooth portions is not particularly limited, and one or three or more tooth portions may be provided on the first support portion 31s. That is, the number of first electrodes 31 may be one or three or more. The second support portion 32s may also be provided in the same manner as the first support portion 31s. The second electrode 32 may also be provided in the same manner as the first electrode 31.

The main surface of the first electrode 31 is perpendicular to the first surface 10t of the glass substrate 10 and parallel to the axis AX of the coil 20. The main surface of the second electrode 32 is similar to the main surface of the first electrode 31.

The glass substrate 10 is positioned between the second tooth portion 312, the first tooth portion 321, the first tooth portion 311, and the second tooth portion 322, and acts as a dielectric.

A fourth protective layer 18 covers the base portion 313 and the base portion 323, and is provided to the second surface 10b of the glass substrate 10. The second protective layer 16 covers the fourth protective layer 18 and is provided to the side of the fourth protective layer 18 opposite to the glass substrate 10.

The first through conductor 23 is connected to the second coil conductor 21b via an eighth via conductor (not illustrated) penetrating the fourth protective layer 18. The eighth via conductor includes an eighth pad portion connected to the first through conductor 23 and an eighth coil wiring connected to the eighth pad portion.

The second through conductor 24 is connected to the second coil conductor 21b via a tenth via conductor 241v penetrating the fourth protective layer 18. The tenth via conductor 241v includes a tenth pad portion 241v1 connected to the second through conductor 24 and a tenth via wiring 241v2 connected to the tenth pad portion 241v1.

The second coil conductor 21b is provided on the fourth protective layer 18 when viewed from a direction perpendicular to the second surface 10b.

The first through conductor 23 closest to the first end surface 10e1 is connected to the first external terminal 41 via the second end 313b of the base portion 313, the eighth via conductor, and a ninth via conductor (not illustrated) provided on the eighth via conductor. The eighth via conductor includes the eighth pad portion provided on the first through conductor 23 and an eighth via wiring provided on the eighth pad portion. The ninth via conductor includes a ninth pad portion provided on the eighth via wiring and a ninth via wiring provided on the ninth pad portion and connected to the first external terminal 41.

The second through conductor 24 closest to the second end surface 10e2 is connected to the second external terminal 42 via the second end 323b of the base portion 323, the tenth via conductor 241v, and an eleventh via conductor 242v provided on the tenth via conductor 241v. In the present embodiment, unlike the first embodiment, the second through conductor 24 overlaps the tenth via conductor 241v and the eleventh via conductor 242v in the direction perpendicular to the first surface 10t, that is, in plan view. The tenth via conductor 241v includes the tenth pad portion 241v1 provided on the second through conductor 24 and the tenth via wiring 241v2 provided on the tenth pad portion 241v1. The eleventh via conductor 242v includes an eleventh pad portion 242v 1 provided on the tenth via wiring 241v2 and an eleventh via wiring 242v2 provided on the eleventh pad portion 242v 1 and connected to the second external terminal 42.

### Eleventh Embodiment

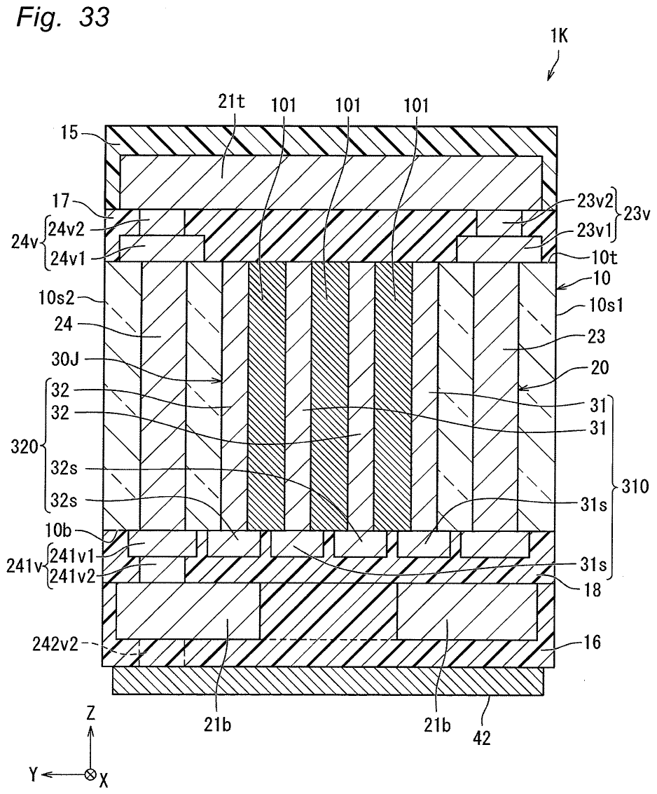

FIG. 33 is a cross-sectional view of an electronic component 1K. FIG. 33 corresponds to FIG. 31 of the tenth embodiment. The eleventh embodiment is different from the tenth embodiment in the structure of the dielectric of a capacitor 30J. This different configuration will be described below. The other configurations are the same as those of the tenth embodiment, and the description thereof will be omitted.

A crystallized portion 101 is positioned at least partially between the first electrode 31 and the second electrode 32. With the above configuration, the crystallized portion 101 that is crystallized glass having a higher Q value than normal glass is positioned between the first electrode 31 and the second electrode 32 of the capacitor 30J. The crystallization portion 101 reduces the dielectric loss of the electronic component 1K, and provides higher reliability for the electronic component 1K. In addition, since it is not necessary to provide the generally used dielectric film 33, the electronic component IJ can be manufactured at a lower cost. In the present embodiment, the crystallized portion 101 is positioned in the entire region between the first electrode 31 and the second electrode 32. The crystallized portion 101 may be positioned in a part between the first electrode 31 and the second electrode 32.

The crystallized portion 101 is a crystallized portion of the glass substrate 10. The transparency of the crystallized portion 101 is lower than the transparency of a portion in a non-crystallized amorphous state which is the other portion of the glass substrate 10. By providing the crystallized portion 101, the effective dielectric constant of the glass substrate 10 can be adjusted. That is, the stray capacitance formed between the first electrode 31 and the second electrode 32 can be increased or decreased, and in particular, the self-resonance frequency of the electronic component 1K can be adjusted. For example, when the glass substrate 10 is FoturanII, while the dielectric constant of the glass substrate 10 is 6.4, the dielectric constant of the crystallized portion 101 can be reduced to 5.8. As a result, the stray capacitance between conductors in the vicinity of the crystallized portion 101 can be reduced.

The crystallized portion 101 can be formed by irradiating a portion of the glass substrate 10 to be crystallized with an ultraviolet ray and then performing a heat treatment (for example, firing). The irradiation with ultraviolet rays can be performed by irradiating the glass substrate 10 with ultraviolet rays having a wavelength of about 310 nm. By the irradiation of the ultraviolet rays, for example, metal ions such as cerium ions of the glass substrate 10 are oxidized by light energy to emit electrons. In a case where the crystallized portion 101 is positioned in a part between the first electrode 31 and the second electrode 32, the processing depth of the crystallized portion 101 can be controlled by adjusting the irradiation amount of the ultraviolet rays according to the thickness of the glass substrate 10.

As an exposure device used for the irradiation of ultraviolet rays, a contact aligner or a stepper capable of obtaining the ultraviolet rays having a wavelength of about 310 nm can be used. In addition, a laser irradiation device including a femtosecond laser can also be used as a light source. In a case where the femtosecond laser is used, electrons can be emitted from the metal oxide only at the condensing portion by condensing the laser light inside the glass substrate 10. That is, the surface of the laser light irradiation unit of the glass substrate 10 is not exposed to light, and only the inside thereof can be exposed to light.

Note that crystallization may be performed after the first electrode 31 and the second electrode 32 are provided to the glass substrate 10, or the first electrode 31 and the second electrode 32 may be provided after the crystallized portion 101 is formed.

### Twelfth Embodiment

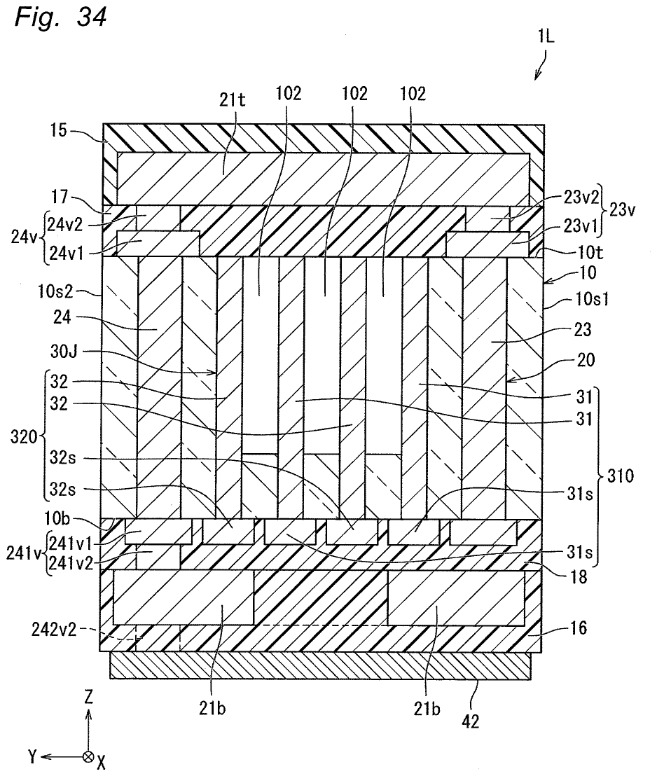

FIG. 34 is a cross-sectional view of an electronic component 1L. FIG. 34 corresponds to FIG. 31 of the tenth embodiment. The twelfth embodiment is different from the tenth embodiment in the structure of the dielectric of a capacitor 30J. This different configuration will be described below. The other configurations are the same as those of the tenth embodiment, and the description thereof will be omitted.

A cavity 102 is formed at least partially between the first electrode 31 and the second electrode 32. With the above configuration, the cavity 102 having a Q value higher than that of the glass substrate 10 is formed between the first electrode 31 and the second electrode 32 of the capacitor 30J. As a result, the dielectric loss of the electronic component 1L is reduced, and higher reliability can be obtained for the electronic component 1L. In addition, since it is not necessary to provide the generally used dielectric film 33, the electronic component 1L can be manufactured at a lower cost. Note that the space between the first electrode 31 and the second electrode 32 may be entirely hollow. In the cavity, no solid or liquid is present, and gas such as air is present.

Note that the present disclosure is not limited to the above-described embodiments, and can be modified in design without departing from the gist of the present disclosure. For example, the respective feature points of the first to twelfth embodiments may be variously combined.

The present disclosure includes the following aspects.
<1> An electronic component comprising a glass substrate having a first surface and a second surface that are positioned on opposite sides from each other; a coil a portion of which is embedded in the glass substrate and which is wound about an axis; and a capacitor provided to the glass substrate, electrically connected to the coil, and having a first electrode and a second electrode that face each other. The first electrode and the second electrode overlap the coil in a direction perpendicular to the axis.
<2> The electronic component according to <1>, wherein the capacitor is arranged inside the coil.
<3> The electronic component according to <1> or <2>, wherein a main surface of the first electrode and a main surface of the second electrode are parallel to the axis of the coil.
<4> The electronic component according to any one of <1> to <3>, further comprising an external terminal on a side of the second surface of the glass substrate. The capacitor is provided on the second surface of the glass substrate and is electrically connected to the external terminal.
<5>T he electronic component according to any one of <1> to <4>, wherein the capacitor includes a dielectric film arranged between the first electrode and the second electrode, the coil includes a through conductor penetrating the glass substrate from the first surface toward the second surface, the through conductor is connected to the first electrode of the capacitor, and the through conductor and the dielectric film are separated from each other when viewed from a direction perpendicular to the first surface.
<6> The electronic component according to any one of <1> to <5>, wherein the coil includes a first end and a second end, and the capacitor is connected to the first end and is positioned closer to a side of the first end than a side of the second end.
<7> The electronic component according to any one of <1> to <6>, wherein a number of turns of the coil is less than one turn, and the coil includes a first through conductor penetrating the glass substrate from the second surface toward the first surface, a first coil conductor connected to the first through conductor and provided on the glass substrate, and a second through conductor connected to the first coil conductor and penetrating the glass substrate from the first surface toward the second surface. Also, the capacitor is provided on the second surface of the glass substrate and is connected to the first through conductor.
<8> The electronic component according to <7>, further comprising a protective layer provided on the second surface and covering the capacitor; and a first external terminal and a second external terminal provided on the protective layer. The first external terminal and the coil are connected via a first via conductor penetrating the protective layer, the second external terminal and the capacitor are connected via a second via conductor penetrating the protective layer, and the capacitor is arranged closer to a side of the second external terminal than a side of the first external terminal.
<9> The electronic component according to <8>, wherein the first via conductor includes a pad portion connected to the first through conductor and a via portion connected to the pad portion and the first external terminal, and the first through conductor and the via portion are separated from each other when viewed from a direction perpendicular to the first surface.
<10> The electronic component according to any one of <1> to <9>, further comprising a first protective layer covering a first surface of the glass substrate; and a second protective layer covering a second surface of the glass substrate. The first protective layer is positioned inside an outer periphery of the first surface of the glass substrate when viewed from a direction perpendicular to the first surface, and the second protective layer is positioned inside an outer periphery of the second surface of the glass substrate when viewed from a direction perpendicular to the second surface.
<11> The electronic component according to any one of <1> to <10>, wherein a plurality of at least one of the coil and the capacitor are arranged.
<12> The electronic component according to any one of <1> to <11>, wherein the first electrode and the second electrode are embedded in the glass substrate, and a glass substrate is positioned between the first electrode and the second electrode.
<13> The electronic component according to any one of <1> to <12>, wherein the first electrode and the second electrode are embedded in the glass substrate, and a crystallized portion is formed at least partially between the first electrode and the second electrode.
<14> The electronic component according to any one of <1> to <13>, wherein the first electrode and the second electrode are embedded in the glass substrate, and a cavity is formed at least partially between the first electrode and the second electrode.

What is claimed is:

1. An electronic component comprising:
a glass substrate having a first surface and a second surface that are on opposite sides from each other;
a coil a portion of which is embedded in the glass substrate and which is wound about an axis; and
a capacitor at the glass substrate, electrically connected to the coil, and having a first electrode and a second electrode that face each other,
wherein the first electrode and the second electrode overlap the coil in a direction perpendicular to the axis.

2. The electronic component according to claim 1, wherein
the capacitor is inside the coil.

3. The electronic component according to claim 1, wherein
a main surface of the first electrode and a main surface of the second electrode are parallel to the axis of the coil.

4. The electronic component according to claim 1, further comprising:
an external terminal on a side of the second surface of the glass substrate,
wherein the capacitor is on the second surface of the glass substrate and is electrically connected to the external terminal.

5. The electronic component according to claim 1, wherein
the capacitor includes a dielectric film between the first electrode and the second electrode,
the coil includes a through conductor penetrating the glass substrate from the first surface toward the second surface,
the through conductor is connected to the first electrode of the capacitor, and
the through conductor and the dielectric film are separated from each other when viewed from a direction perpendicular to the first surface.

6. The electronic component according to claim 1, wherein
the coil includes a first end and a second end, and
the capacitor is connected to the first end and is closer to a side of the first end than a side of the second end.

7. The electronic component according to claim 1, wherein
a number of turns of the coil is less than one turn, and the coil includes a first through conductor penetrating the glass substrate from the second surface toward the first surface, a first coil conductor connected to the first through conductor and on the glass substrate, and a second through conductor connected to the first coil conductor and penetrating the glass substrate from the first surface toward the second surface, and
the capacitor is on the second surface of the glass substrate and is connected to the first through conductor.

8. The electronic component according to claim 7, further comprising:
a protective layer on the second surface and covering the capacitor; and
a first external terminal and a second external terminal on the protective layer,
wherein
the first external terminal and the coil are connected via a first via conductor penetrating the protective layer,
the second external terminal and the capacitor are connected via a second via conductor penetrating the protective layer, and
the capacitor is closer to a side of the second external terminal than a side of the first external terminal.

9. The electronic component according to claim 8, wherein
the first via conductor includes a pad portion connected to the first through conductor and a via portion connected to the pad portion and the first external terminal, and
the first through conductor and the via portion are separated from each other when viewed from a direction perpendicular to the first surface.

10. The electronic component according to claim 1, further comprising:
a first protective layer covering a first surface of the glass substrate; and
a second protective layer covering a second surface of the glass substrate,
wherein
the first protective layer is inside an outer periphery of the first surface of the glass substrate when viewed from a direction perpendicular to the first surface, and
the second protective layer is inside an outer periphery of the second surface of the glass substrate when viewed from a direction perpendicular to the second surface.

11. The electronic component according to claim 1, comprising:
a plurality of at least one of the coil and the capacitor.

12. The electronic component according to claim 1, wherein
the first electrode and the second electrode are embedded in the glass substrate, and
a glass substrate is between the first electrode and the second electrode.

13. The electronic component according to claim 1, wherein
the first electrode and the second electrode are embedded in the glass substrate, and
a crystallized portion is at least partially between the first electrode and the second electrode.

14. The electronic component according to claim 1, wherein
the first electrode and the second electrode are embedded in the glass substrate, and
a cavity is at least partially between the first electrode and the second electrode.

15. The electronic component according to claim 2, wherein
a main surface of the first electrode and a main surface of the second electrode are parallel to the axis of the coil.

16. The electronic component according to claim 2, further comprising:
an external terminal on a side of the second surface of the glass substrate,
wherein the capacitor is on the second surface of the glass substrate and is electrically connected to the external terminal.

17. The electronic component according to claim 2, wherein
the capacitor includes a dielectric film between the first electrode and the second electrode,
the coil includes a through conductor penetrating the glass substrate from the first surface toward the second surface,
the through conductor is connected to the first electrode of the capacitor, and
the through conductor and the dielectric film are separated from each other when viewed from a direction perpendicular to the first surface.

18. The electronic component according to claim 2, wherein
the coil includes a first end and a second end, and
the capacitor is connected to the first end and is closer to a side of the first end than a side of the second end.

19. The electronic component according to claim 2, wherein
a number of turns of the coil is less than one turn, and the coil includes a first through conductor penetrating the glass substrate from the second surface toward the first surface, a first coil conductor connected to the first through conductor and on the glass substrate, and a second through conductor connected to the first coil conductor and penetrating the glass substrate from the first surface toward the second surface, and
the capacitor is on the second surface of the glass substrate and is connected to the first through conductor.

20. The electronic component according to claim 2, further comprising:
a first protective layer covering a first surface of the glass substrate; and
a second protective layer covering a second surface of the glass substrate,
wherein
the first protective layer is inside an outer periphery of the first surface of the glass substrate when viewed from a direction perpendicular to the first surface, and
the second protective layer is inside an outer periphery of the second surface of the glass substrate when viewed from a direction perpendicular to the second surface.
